(19) United States
(12) Patent Application Publication
(10) Pub. No.: US 2024/0337933 A1
(43) Pub. Date: Oct. 10, 2024

(54) RESIST TOPCOAT COMPOSITION AND METHOD OF FORMING PATTERNS USING THE COMPOSITION

(71) Applicants: SAMSUNG SDI CO., LTD., Yongin-si (KR); SAMSUNG ELECTRONICS CO., LTD., Suwon-si (KR)

(72) Inventors: Ran NAMGUNG, Suwon-si (KR); Kyoungjin HA, Suwon-si (KR); Hyeon PARK, Suwon-si (KR); Daeseok SONG, Suwon-si (KR); Minsoo KIM, Suwon-si (KR); Sanghyun JE, Suwon-si (KR); Jun Soo KIM, Suwon-si (KR); Soyeon YOO, Suwon-si (KR); Su Min PARK, Suwon-si (KR); Suk-Koo Hong, Suwon-si (KR)

(21) Appl. No.: 18/536,373

(22) Filed: Dec. 12, 2023

(30) Foreign Application Priority Data
Apr. 7, 2023 (KR) 10-2023-0046247

(51) Int. Cl. G03F 7/004; C08F 114/16; C08F 220/18; C08F 220/22; C08K 5/05; C08K 5/06; H01L 21/027

(52) U.S. Cl. CPC G03F 7/0048; C08F 114/16; C08F 220/1806; C08F 220/22; C08K 5/05; C08K 5/06; H01L 21/0274

(57) ABSTRACT

A resist topcoat composition and a method of forming patterns utilizing the resist topcoat composition are provided. The resist topcoat composition includes a copolymer including a first structural unit represented by Chemical Formula M-1 and a second structural unit represented by Chemical Formula M-2; and a solvent.

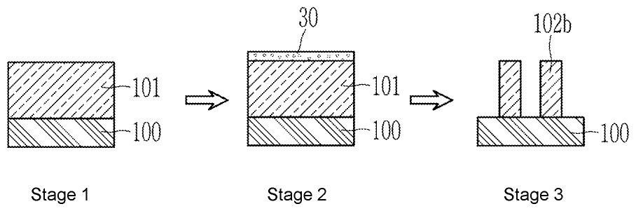

### CROSS-REFERENCE TO RELATED APPLICATION

This application claims priority to and the benefit of Korean Patent Application No. 10-2023-0046247, filed on Apr. 7, 2023, in the Korean Intellectual Property Office, the entire content of which is incorporated herein by reference.

### BACKGROUND

### 1. Field

This disclosure relates to a resist topcoat composition and a method of forming patterns utilizing the same.

### 2. Description of the Related Art

Recently, the semiconductor industry has developed the utilization of an ultrafine technique having a pattern with dimensions of a few nanometer, to several tens of nanometers, in size. Implementation of a suitable ultrafine technique essentially requires (or there is a desire for) effective photolithographic processes capable of producing the proper dimensions.

Comparable photolithographic processes include forming a material layer on a semiconductor substrate, coating a photoresist film thereon, exposing and developing to form a photoresist pattern, and then etching the material layer utilizing the photoresist pattern as a mask. As photolithography processes develop, a degree of pattern integration is increasing, and materials and technologies for solving the numerous challenges presented by the requirements (e.g., desires) of this process are continuously needed.

For example, if (e.g., when) extreme ultraviolet (EUV) wavelength light is irradiated onto (e.g., to) the photoresist, there may be one or more regions where more (e.g., lots of) or less (e.g., little) than the intended quantity of light is randomly irradiated. This may occur due to an excessive (e.g., large) amount of energy per photon, which is termed a “photo shot noise.” The random irradiation may also be the result of an EUV absorption difference between the top and the bottom of the photoresist which may cause pattern distribution deterioration such as roughness (e.g., LER: line edge roughness, and/or LWR: line width roughness) or IPU (in-point uniformity) of the patterns. Accordingly, successful implementation of a photolithographic processes to enhance or improve this pattern distribution deterioration requires (or there is a desire for) the development of resist topcoat composition technology.

### SUMMARY

One or more aspects of embodiments of the present disclosure are directed toward a resist topcoat composition capable of reducing pattern distribution by preventing or reducing pattern deterioration.

One or more aspects of embodiments of the present disclosure are directed toward a method of forming patterns utilizing the resist topcoat composition. Additional aspects will be set forth in part in the description which follows and, in part, will be apparent from the description, or may be learned by practice of the presented embodiments of the disclosure.

One or more embodiments provides a resist topcoat composition including a copolymer including a first structural unit represented by Chemical Formula M-1 and a second structural unit represented by Chemical Formula M-2; and a solvent.

The first structural unit may be represented by Chemical Formula 1.

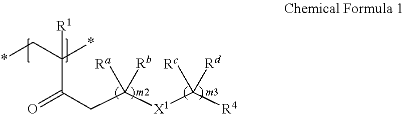

In Chemical Formula 1,
R¹ may be hydrogen or a substituted or unsubstituted C1 to C10 alkyl group,
R^{a}, R^{b}, R^{c}, R^{d}, and R⁴ may each independently be hydrogen, a fluorine, a hydroxyl group, a substituted or unsubstituted C1 to C20 alkyl group, or a combination thereof,
m2 and m3 may each independently be one of an integer of 1 to 10,
X¹ may be a single bond, —O—, —S—, —S(O)—, —S(O)₂—, —C(O)—, —(CO)O—, —O(CO), —O(CO)O—, —NR′— (wherein, R′ is hydrogen, deuterium, or a C1 to C10 alkyl group), or a combination thereof, and
at least one of R^{a}, R^{b}, R^{c}, R^{d}, and R⁴ includes fluorine and a hydroxyl group.

For example, at least one of R^{c}, R^{d}, and R⁴ in Chemical Formula 1 includes fluorine and a hydroxyl group.

As an example, at least one of R^{c} and R^{d} in Chemical Formula 1 may be fluorine or a C1 to C10 alkyl group substituted with at least one fluorine, and R⁴ may be a hydroxyl group or a C1 to C10 alkyl group substituted with at least one hydroxyl group.

As an example, at least one of R^{c} and R^{d} in Chemical Formula 1 may be a hydroxyl group or a C1 to C10 alkyl group substituted with at least one hydroxyl group, and R⁴ may be a fluorine or a C1 to C10 alkyl group substituted with at least one fluorine.

As an example, in Chemical Formula 1, R^{c} may be a hydroxyl group or a C1 to C10 alkyl group substituted with at least one hydroxyl group, R^{d} may be fluorine or a C1 to C10 alkyl group substituted with at least one fluorine, and R⁴ may be a hydroxyl group, fluorine, or a C1 to C10 alkyl group substituted with at least one of fluorine and a hydroxyl group.

The first structural unit may be selected from Group I.

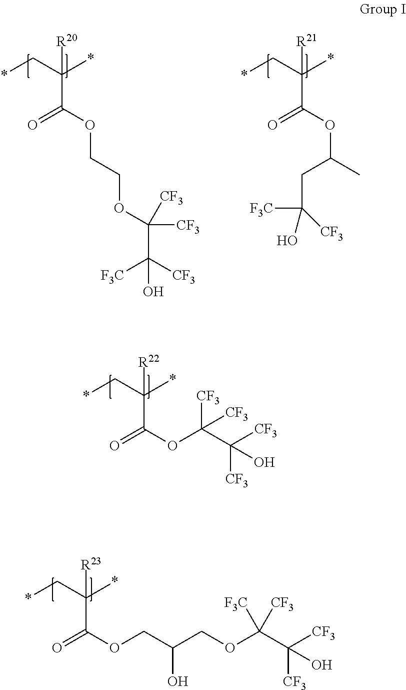

In Group I,
R²⁰ to R²³ may each independently be hydrogen or a methyl group, and * may be a linking point.

The second structural unit may be represented by any one of Chemical Formulas 2-1 to 2-3.

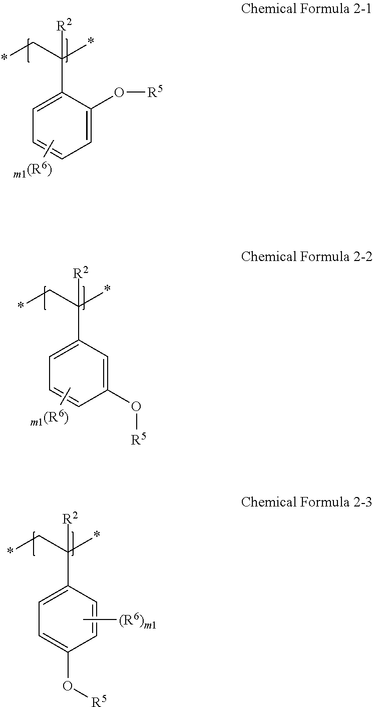

In Chemical Formulas 2-1 and 2-2,
R² may be hydrogen or a methyl group,
R⁵ may be hydrogen or C(═O)R⁷,
R⁷ may be a substituted or unsubstituted C1 to C5 alkyl group,
each R⁶ may independently be hydrogen, a halogen, a hydroxyl group, a substituted or unsubstituted C1 to C5 alkyl group, or a combination thereof,
m1 may be an integer of 1 to 4, and
* may be a linking point.

At least one of R⁶ may be a halogen.

At least one of R⁶ may be an iodine group.

The second structural unit may be selected from Group II.

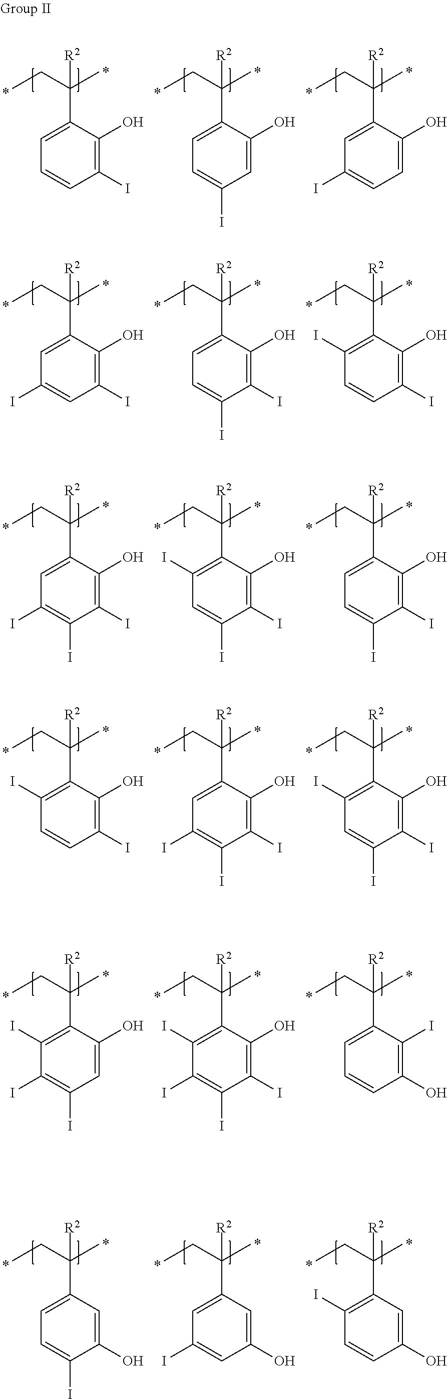

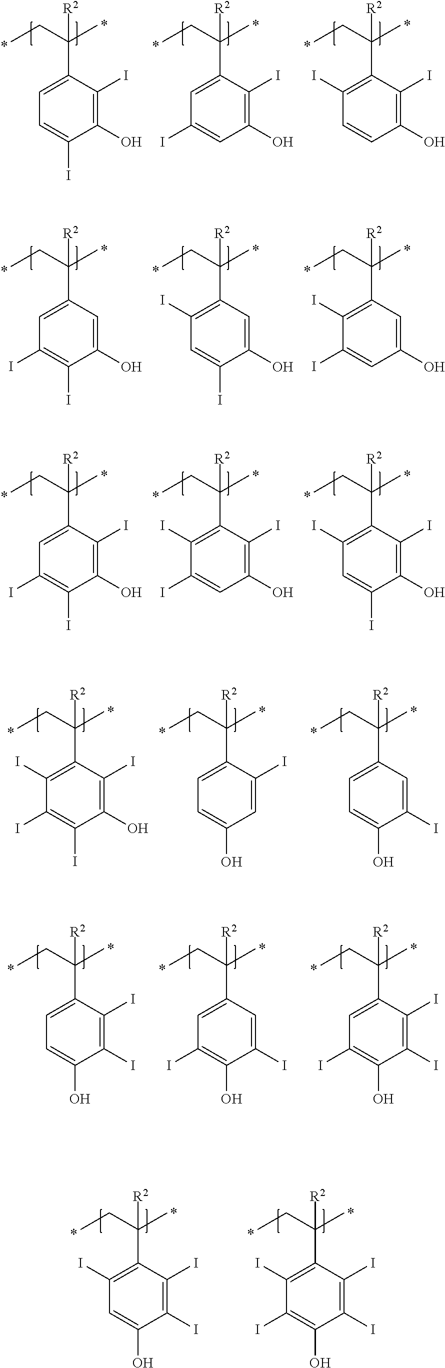

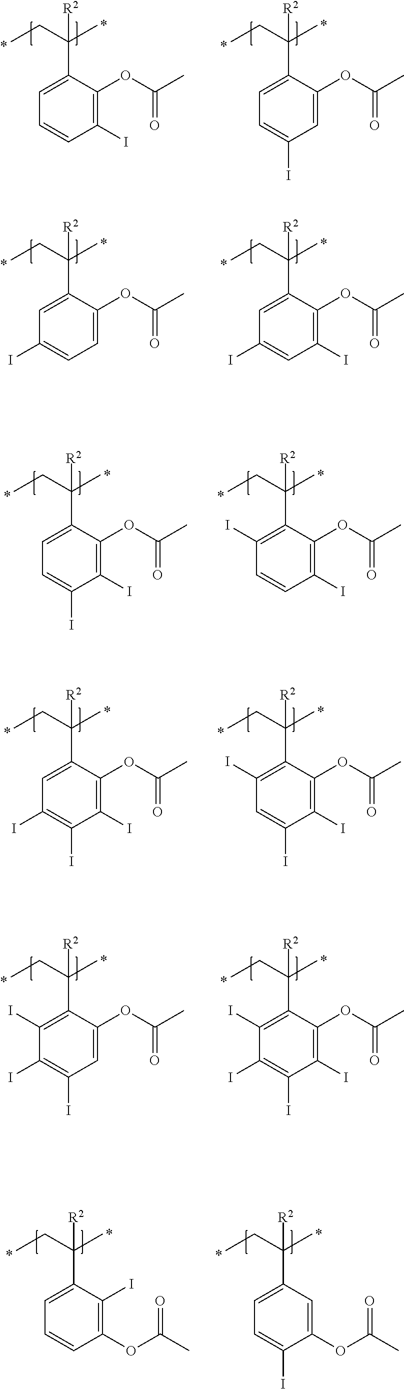

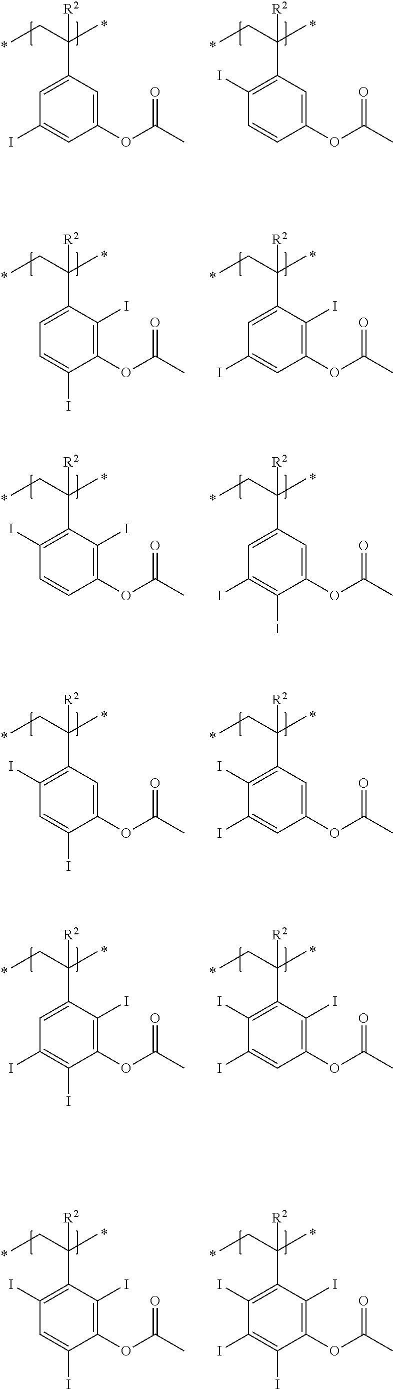

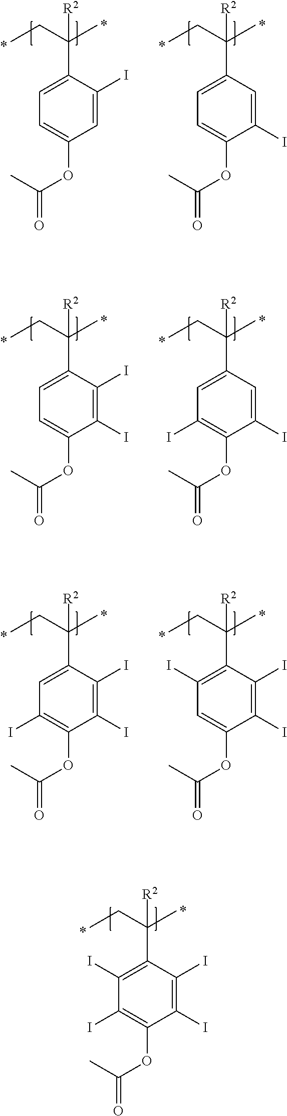

In Group II,
R² may be hydrogen or a methyl group, and * may be a linking point.

In some example embodiments, the copolymer may further include a third structural unit represented by Chemical Formula M-3.

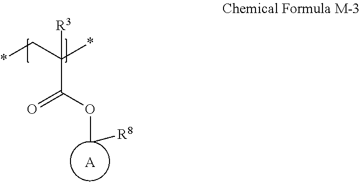

In Chemical Formula M-3,
R³ may be hydrogen or a substituted or unsubstituted C1 to C10 alkyl group,
A may be a substituted or unsubstituted C4 to C30 monocyclic aliphatic ring group or a substituted or unsubstituted C7 to C50 polycyclic aliphatic ring group, and A may be linked to a copolymer main chain (i.e., the polymer backbone of the copolymer) by a quaternary carbon,
R⁸ may be a substituted or unsubstituted C1 to C10 alkyl group, and
* may be a linking point.

A may be a substituted or unsubstituted cyclobutyl group, a substituted or unsubstituted cyclopentyl group, a substituted or unsubstituted cyclohexyl group, a substituted or unsubstituted cyclooctyl group, a substituted or unsubstituted bicyclohexyl group, a substituted or unsubstituted bicycloheptyl group, a substituted or unsubstituted bicyclooctyl group, a substituted or unsubstituted bicyclononyl group, a substituted or unsubstituted bicyclodecanyl group, a substituted or unsubstituted tricyclodecanyl group, or a substituted or unsubstituted tetracyclodecanyl group, and A may be linked to the copolymer main chain (i.e., the polymer backbone of the copolymer) by a quaternary carbon.
A may be selected from Group III.

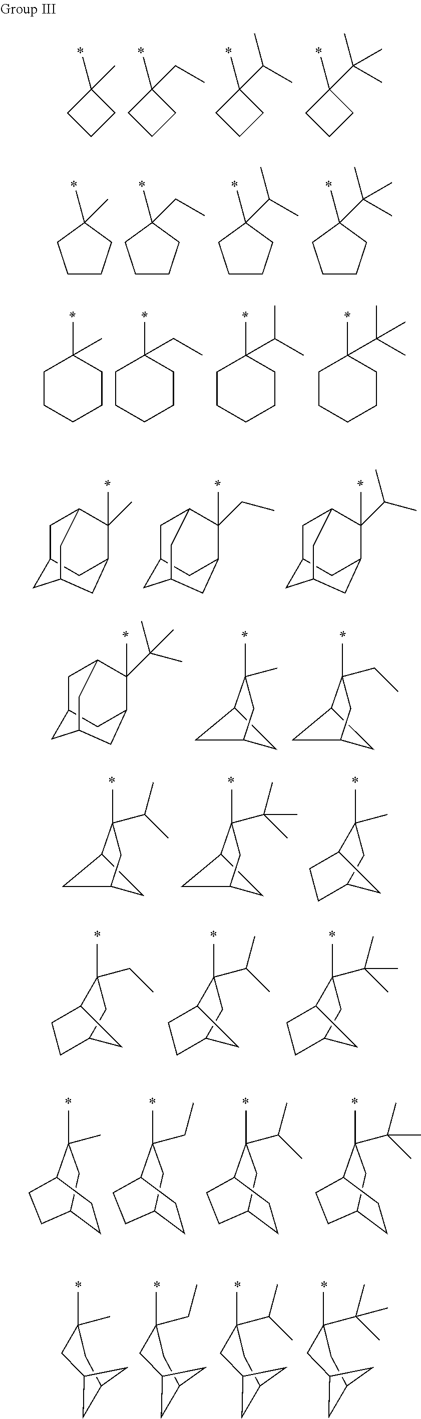

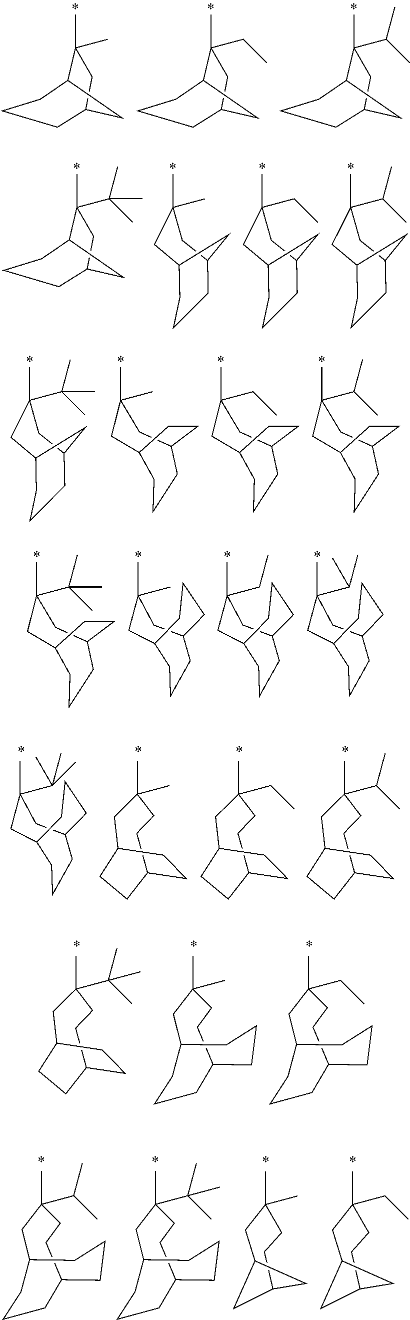

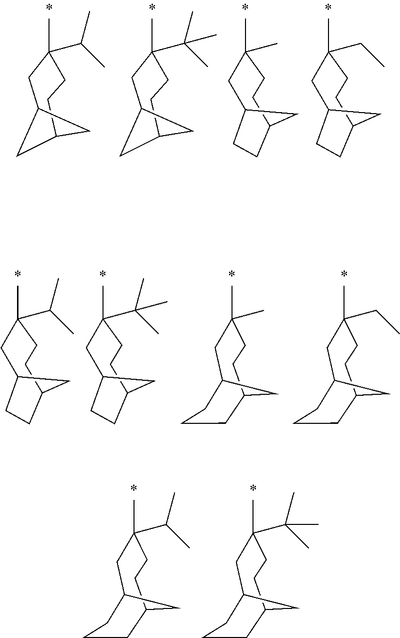

In Group III, * may be a linking point.

The copolymer according to some example embodiments may include about 30 to about 95 mole percent (i.e., percentage based on molar amounts) (mol %) of the first structural unit, about 1 to about 20 mol % of the second structural unit, and about 5 to about 50 mol % of the third structural unit.

The copolymer according to some example embodiments may have a weight average molecular weight of about 1,000 gram per mole (g/mol) to about 50,000 g/mol.

The copolymer according to some example embodiments may be included in an amount of 0.1 weight percent (i.e., percentage based on weight or mass) (wt %) to 10 wt % based on a total weight of the resist topcoat composition.

In some example embodiments, a photodecomposable quencher (PDQ) including a cation represented by Chemical Formula 3A or 3B and an anion represented by Chemical Formula 4A or 4B may be further included (e.g., in the resist topcoat composition).

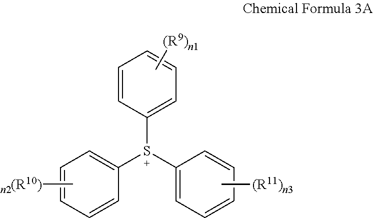

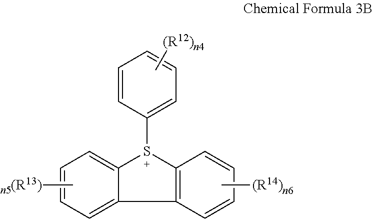

In Chemical Formulas 3A and 3B,
R⁹ to R¹⁴ may each independently be hydrogen, a halogen, a carboxyl group, a substituted or unsubstituted C1 to C10 alkoxy group, or a substituted or unsubstituted C1 to C20 alkyl group, and
n1 to n6 may each independently be an integer of 1 to 5;

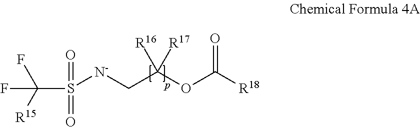

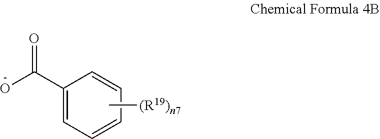

wherein, in Chemical Formulas 4A and 4B,
R¹⁵ to R¹⁷ may each independently be hydrogen, a halogen, a carboxyl group, a substituted or unsubstituted C1 to C10 alkoxy group, or a substituted or unsubstituted C1 to C20 alkyl group,
R¹⁸ may be a substituted or unsubstituted C1 to C20 alkyl group, a substituted or unsubstituted C5 to C30 monocyclic aliphatic ring group, or a substituted or unsubstituted C7 to C50 polycyclic aliphatic ring group,
R¹⁹ may be hydrogen, a halogen, a hydroxyl group, a carboxyl group, a substituted or unsubstituted C1 to C10 alkoxy group, or a substituted or unsubstituted C1 to C20 alkyl group,
p may be an integer of 1 to 20, and
n7 may be an integer of 1 to 5.
R⁹ to R¹⁴ may each independently be hydrogen, a fluoro group, an iodo group, or a substituted or unsubstituted C1 to C10 alkyl group.

The photodecomposable quencher (PDQ) may be represented by Chemical Formula Q1, Chemical Formula Q2, or Chemical Formula Q3.

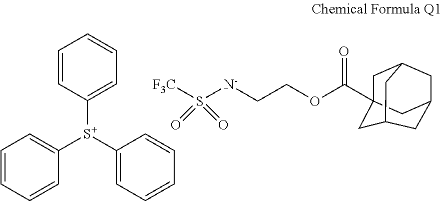 [SMILES: c1ccc([S+](c2ccccc2)c2ccccc2)cc1 ; O=C(OCC[N-]S(=O)(=O)C(F)(F)F)C12CC3CC(CC(C3)C1)C2]

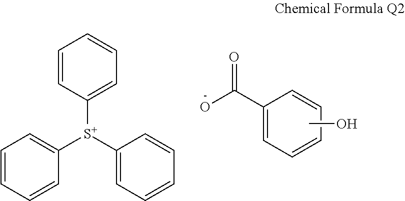

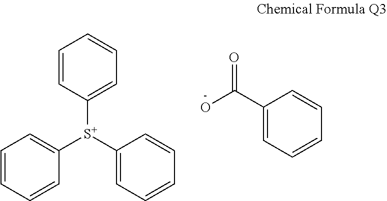 [SMILES: c1ccc([S+](c2ccccc2)c2ccccc2)cc1 ; O=C(O)c1ccccc1]

The photodecomposable quencher (PDQ) may be included in an amount of about 0.1 to about 20 parts by weight based on 100 parts by weight of the copolymer.

The copolymer according to some example embodiments may include about 70 to about 99 mol % of the first structural unit and about 1 to about 30 mol % of the second structural unit.

The copolymer according to some example embodiments may have a weight average molecular weight of about 1,000 g/mol to about 50,000 g/mol.

The copolymer according to some example embodiments may be included in an amount of about 0.1 wt % to about 10 wt % based on a total weight of the resist topcoat composition.

According to some example embodiments, the solvent may be an ether-based solvent.

According to some example embodiments, the solvent may be a mixed solvent of an ether-based solvent and an alcohol-based solvent.

The mixed solvent may include the ether-based solvent and the alcohol-based solvent in a mass ratio of about 99.9:0.1 to about 80:20.

The ether-based solvent may be represented by Chemical Formula 5.

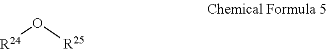

In Chemical Formula 5,
R²⁴ and R²⁵ may each independently be a substituted or unsubstituted C3 to C20 alkyl group.

Some example embodiments provide a method of forming patterns which includes coating and heating a photoresist composition on a substrate to form a photoresist film, coating and heating the resist topcoat composition disclosed herein on the photoresist film to form a photoresist topcoat, and exposing and developing the photoresist topcoat and the photoresist film to form the patterns (e.g., resist patterns).

The resist topcoat composition according to some example embodiments may remove excessively activated acid from the top of the photoresist film, if (e.g., when) exposed with extreme ultraviolet (EUV), to prevent or reduce the pattern distribution deterioration. In some embodiments, the pattern distribution deterioration may include roughness, such as line edge roughness (LER), or line width roughness (LWR). In some embodiments, the pattern distribution deterioration may include in-point uniformity (IPU) of the patterns due to an EUV absorption difference between the top and the bottom of a photoresist film and this may thus improve the pattern distribution and significantly improve IPU of pillar patterns, thereby advantageously contributing to form fine patterns (e.g., in or of the photoresist film).

### BRIEF DESCRIPTION OF THE DRAWING

The accompanying drawing is included to provide a further understanding of the present disclosure, and is incorporated in and constitutes a part of this specification. The drawing illustrates an example embodiment, and facilitates explanation of the principles of the present disclosure, together with the detailed description.

The drawing is a schematic view for explaining a method of forming patterns utilizing a resist topcoat composition according to some example embodiments of the present disclosure.

### DETAILED DESCRIPTION

Example embodiments of the present disclosure will hereinafter be described in more detail, and may be easily performed by a person skilled in the art. However, this disclosure may be embodied in many different forms and is not construed as limited to the example embodiments set forth herein, rather the present disclosure is defined by the scope of claims. In this regard, the present embodiments may have different forms and should not be construed as being limited to the descriptions set forth herein, and it is to be appreciated that all changes, equivalents, and substitutes that do not depart from the spirit and technical scope are encompassed in the present disclosure.

In the drawing, the thickness of layers, films, panels, regions, and/or the like, are exaggerated for clarity and like reference numerals designate like elements throughout, and duplicative descriptions thereof may not be provided the specification. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe various elements, these elements should not be limited by these terms. These terms are only used to distinguish one element from another element. Thus, a first element could be termed a second element without departing from the teachings of the present disclosure. Similarly, a second element could be termed a first element.

As used herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, alternative language such as “or” is not to be construed as an exclusive meaning, for example, “A or B” is construed to include A, B, A+B, and/or the like. Similarly, the term “and/or” includes any and all combinations of one or more of the associated listed items. The symbol “/” utilized herein may be interpreted as “and” or “or” according to the context.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added. The term “combination thereof” may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element.

In this context, “consisting essentially of” means that any additional components will not materially affect the chemical, physical, optical or electrical properties of the semiconductor film.

### Definitions

As utilized herein, if (e.g., when) a definition is not otherwise provided, “substituted” refers to replacement of a hydrogen atom of a compound by a substituent selected from among a halogen atom (F, Br, Cl, or I), a hydroxyl group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As utilized herein, if (e.g., when) a definition is not otherwise provided, “hetero” refers to one including 1 to 10 heteroatoms selected from among N, O, S, and P.

In some embodiments, in the present specification, the acrylic polymer refers to an acrylic polymer and a methacrylic polymer.

In some embodiments, in the present specification, the acrylic polymer refers to an acrylic polymer and a methacrylic polymer.

Unless otherwise specified in the present specification, the weight average molecular weight is measured by dissolving a powder sample in tetrahydrofuran (THF) and then utilizing 1200 series Gel Permeation Chromatography (GPC) of Agilent Technologies (column is Shodex Company LF-804, standard sample is Shodex company polystyrene).

In some embodiments, unless otherwise defined in the specification, indicates a linking point of a structural unit or a compound moiety of a compound.

Hereinafter, a resist topcoat composition according to some example embodiments is described.

### Resist Topcoat Composition

The present disclosure relates to a resist (e.g., photoresist) topcoat composition capable of improving at least one of IPU (in-point uniformity) of C/H (contact hole) patterns, LER (line edge roughness) and/or LWR (line width roughness) of L/S (line and space) patterns, or improving IPU of pillar patterns. In some embodiments, present disclosure relates to enhancing or improving the sensitivity of a photoresist (e.g., film) during the fine pattern-forming process of photolithography by utilizing high-energy electromagnetic radiation rays such as EUV (extreme ultraviolet, wavelength: about 13.5 nm) and/or the like and concurrently (e.g., simultaneously), selectively reducing an acid concentration of an upper portion of the photoresist (e.g., film). In some embodiments, the present disclosure relates to a method of forming patterns (e.g., resist (e.g., photoresist)) patterns by utilizing the resist (e.g., photoresist) topcoat composition described herein.

The resist topcoat composition according to some example embodiments includes a copolymer including a first structural unit represented by Chemical Formula M-1 and a second structural unit represented by Chemical Formula M-2; and a solvent.

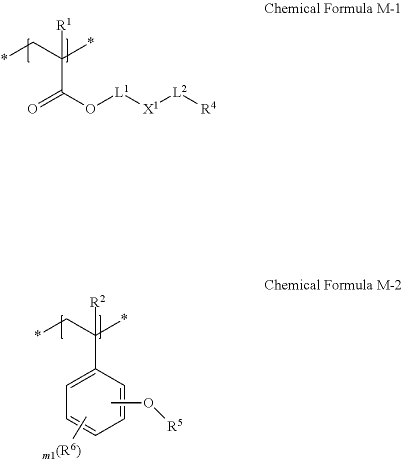

In Chemical Formulas M-1 and M-2,
R¹ and R² may each independently be hydrogen or a substituted or unsubstituted C1 to C10 alkyl group,
L¹ and L² may each independently be a single bond, a substituted or unsubstituted C1 to C10 alkylene group, or a combination thereof,
X¹ may be a single bond, —O—, —S—, —S(O)—, —S(O)₂—, —C(O)—, —(CO)O—, —O(CO), —O(CO)O—, —NR′— (where R′ is hydrogen, deuterium, or a C1 to C10 alkyl group), or a combination thereof,
R⁴ may be hydrogen, fluorine, a hydroxyl group, a substituted or unsubstituted C1 to C20 alkyl group, or a combination thereof,
R⁵ may be hydrogen or C(═O)R⁷,
R⁷ may be a substituted or unsubstituted C1 to C10 alkyl group,
at least one of R⁴, L¹ and L² includes fluorine and a hydroxyl group,
each R⁶ may independently be hydrogen, a halogen, a hydroxyl group, a substituted or unsubstituted C1 to C10 alkyl group, or a combination thereof, and
m1 may be an integer of 1 to 4.

As an example, the copolymer may further include a third structural unit represented by Chemical Formula M-3.

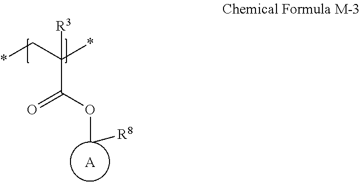

In Chemical Formula M-3,
R³ may be hydrogen or a substituted or unsubstituted C1 to C10 alkyl group,
A may be a substituted or unsubstituted C4 to C30 monocyclic aliphatic ring group or a substituted or unsubstituted C7 to C50 polycyclic aliphatic ring, and A may be a group linked to the copolymer main chain (i.e., the polymer backbone of the copolymer) by a quaternary carbon,
R⁸ may be a substituted or unsubstituted C1 to C10 alkyl group, and
* may be a linking point.

As another example, the resist topcoat composition may further include a photodecomposable quencher (PDQ) including a cation represented by Chemical Formula 3A or 3B and an anion represented by Chemical Formula 4A or 4B.

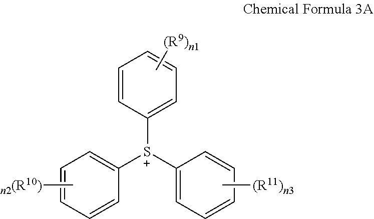

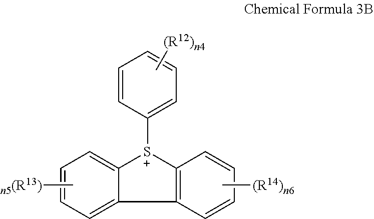

In Chemical Formulas 3A and 3B,
R⁹ to R¹⁴ may each independently be hydrogen, a halogen, a carboxyl group, a substituted or unsubstituted C1 to C10 alkoxy group, or a substituted or unsubstituted C1 to C20 alkyl group, and
n1 to n6 may each independently be an integer of 1 to 5;

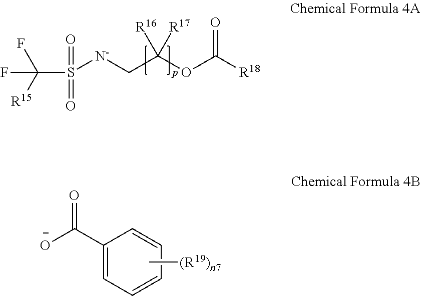

wherein, in Chemical Formulas 4A and 4B,
R¹⁵ to R¹⁷ may each independently be hydrogen, a halogen, a carboxyl group, a substituted or unsubstituted C1 to C10 alkoxy group, or a substituted or unsubstituted C1 to C20 alkyl group,
R¹⁸ may be a substituted or unsubstituted C1 to C20 alkyl group, a substituted or unsubstituted C5 to C30 monocyclic aliphatic ring group, or a substituted or unsubstituted C7 to C50 polycyclic aliphatic ring group,
R¹⁹ may be hydrogen, a halogen, a hydroxyl group, a carboxyl group, a substituted or unsubstituted C1 to C10 alkoxy group, or a substituted or unsubstituted C1 to C20 alkyl group,
p may be an integer of 1 to 20, and
n7 may be an integer of 1 to 5.

The resist (e.g., photoresist) topcoat composition according to some example embodiments may be coated on top of a photoresist film to significantly improve LER/LWR of L/S patterns, IPU of C/H patterns, and/or IPU of pillar patterns, as well as to increase sensitivity of the photoresist (e.g., photoresist film).

In some embodiments, the first structural unit has characteristics of having almost no reactivity (e.g., is unreactive) with the photoresist (e.g., film) and/or being well dissolved in a solvent. In some embodiments, the first structural unit may protect the photoresist (e.g., film), while minimizing or reducing an influence on the photoresist (e.g., film). In some embodiments, the second structural unit may increase EUV absorption to improve sensitivity (e.g., of the photoresist film), the third structural unit may (e.g., selectively) reduce a concentration of acid (e.g., excessively) produced by the exposure on top of the photoresist film. In some embodiments, the third structural unit may improve a round profile on the upper portion of the photoresist (e.g., film) into a rectangular one, resultantly improving IPU or LWR of the patterns.

In some embodiments, the photodecomposable quencher (PDQ) may be utilized to selectively remove the acid activated by the exposure on top of the photoresist film. In some embodiments, the photodecomposable quencher (PDQ) may be utilized to improve the round profile of the upper portion of the photoresist (e.g., film) to the rectangular profile and resultantly, improve IPU or LWR of the patterns.

In some embodiments, the resist (e.g., photoresist) topcoat composition, if (e.g., when) it remains after the development, may cause scum defects in the L/S patterns or not-open defects in the C/H patterns, resulting in decreasing a product yield.

In some embodiments, the resist (e.g., photoresist) topcoat composition according to some example embodiments may be removed during the development process and thus cause no defects in one or more suitable patterns.

In Chemical Formula M-1, the descriptions that at least one of R⁴, L¹, and L² may include fluorine and a hydroxyl group may indicate that
R⁴ may be a C1 to C10 alkyl group substituted with at least one fluorine and at least one hydroxyl group, or
at least one of L¹ and L² may be a C1 to C10 alkyl group substituted with at least one fluorine and at least one hydroxyl group, or
one of L¹ or L² may be a C1 to C10 alkylene group substituted with at least one fluorine, and the other L¹ or L² may be a C1 to C10 allylene group substituted with at least one hydroxyl group, or
R⁴ may be fluorine, and at least one of L¹ and L² may be a C1 to C10 alkylene group substituted with at least one hydroxyl group, or
R⁴ may be a hydroxyl group, and at least one of L¹ and L² may be a C1 to C10 alkylene group substituted with at least one fluorine, or
R⁴ may be a C1 to C10 alkyl group substituted with at least one fluorine and at least one hydroxyl group, or
R⁴ may be a C1 to C10 alkyl group substituted with at least one hydroxyl group and at least one fluorine.

For example, the first structural unit may be represented by Chemical Formula 1.

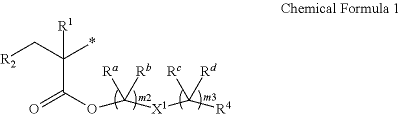

In Chemical Formula 1,
R¹ may be hydrogen or a substituted or unsubstituted C1 to C10 alkyl group,
R^{a}, R^{b}, R^{c}, R^{d}, and R⁴ may each independently be hydrogen, fluorine, a hydroxyl group, a substituted or unsubstituted C1 to C20 alkyl group, or a combination thereof,
m2 and m3 may each independently be an integer of 1 to 10,
X¹ may be a single bond, —O—, —S—, —S(O)—, —S(O)₂—, —C(O)—, —(CO)O—, —O(CO), —O(CO)O—, —NR′— (where R′ is hydrogen, deuterium, or a C1 to C10 alkyl group), or a combination thereof, and
at least one of R^{a}, R^{b}, R^{c}, R^{d}, and R⁴ includes fluorine and a hydroxyl group.

The descriptions that at least one of R^{a}, R^{b}, R^{c}, R^{d}, and R⁴ includes fluorine and a hydroxyl group indicate that
at least one of R^{a}, R^{b}, R^{c}, R^{d}, and R⁴ may each independently be fluorine and a hydroxyl group, or
at least one of R^{a}, R^{b}, R^{c}, R^{d}, and R⁴ may each independently be a C1 to C10 alkyl group substituted with at least one fluorine and a C1 to C10 alkyl group substituted with at least one hydroxyl group, or
at least one of R^{a}, R^{b}, R^{c}, R^{d}, and R⁴ may each independently be a C1 to C10 alkyl group substituted with at least one hydroxyl group and at least one fluorine, or
at least one of R^{a}, R^{b}, R^{c}, R^{d}, and R⁴ may each independently include a C1 to C10 alkyl group substituted with at least one hydroxyl group and at least one fluorine, or
at least one of R^{a}, R^{b}, R^{c}, R^{d}, and R⁴ may be fluorine and at least one of the other R^{a}, R^{b}, R^{c}, R^{d}, and R⁴ may be a hydroxyl group, or
at least one of R^{a}, R^{b}, R^{c}, R^{d}, and R⁴ may be a fluorine and at least one of the other R^{a}, R^{b}, R^{c}, R^{d}, and R⁴ may be a C1 to C10 alkyl group substituted with at least one hydroxyl group, or
at least one of R^{a}, R^{b}, R^{c}, R^{d}, and R⁴ may be a hydroxyl group and at least one of the other R^{a}, R^{b}, R^{c}, R^{d}, and R⁴ may be a C1 to C10 alkyl group substituted with at least one fluorine, or
for example, R¹ may be hydrogen or a methyl group,
X¹ may be a single bond or —O—, and
R⁴ may include at least one of fluorine and a C1 to C10 alkyl group substituted with at least one fluorine, and at least one of a hydroxyl group and a C1 to C10 alkyl group substituted with at least one hydroxyl group.

For example, at least one of R^{c}, R^{d}, and R⁴ in Chemical Formula 1 may include fluorine and a hydroxyl group.

As an example, at least one of R^{c} and R^{d} in Chemical Formula 1 may be fluorine or a C1 to C10 alkyl group substituted with at least one fluorine, and R⁴ may be a hydroxyl group or a C1 to C10 alkyl group substituted with at least one hydroxyl group.

As an example, at least one of R^{c} and R^{d} in Chemical Formula 1 may be a hydroxyl group or a C1 to C10 alkyl group substituted with at least one hydroxyl group and R⁴ may be fluorine or a C1 to C10 alkyl group substituted with at least one fluorine.

As an example, R^{c} in Chemical Formula 1 may be a hydroxyl group or a C1 to C10 alkyl group substituted with at least one hydroxyl group, R^{d} may be fluorine or a C1 to C10 alkyl group substituted with at least one fluorine, and R⁴ may be a hydroxyl group, fluorine, or a C1 to C10 alkyl group substituted with at least one of fluorine or a hydroxyl group.

For example, the first structural unit may be selected from Group I.

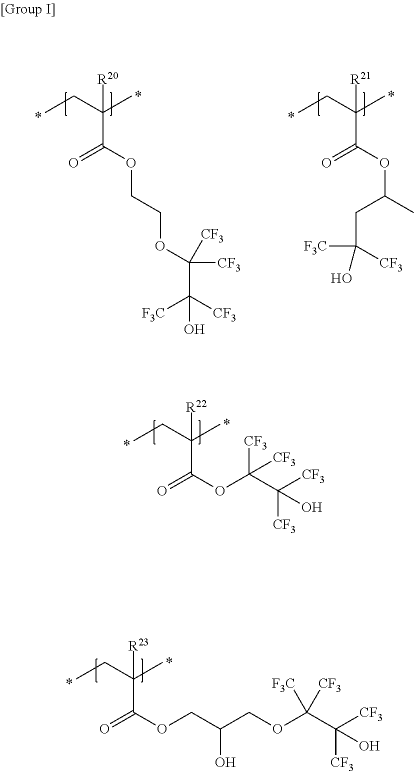

In Group I,
R²⁰ to R²³ may each independently be hydrogen or a methyl group, and * may be a linking point.

For example, the second structural unit may be represented by any one of Chemical Formulas 2-1 to 2-3.

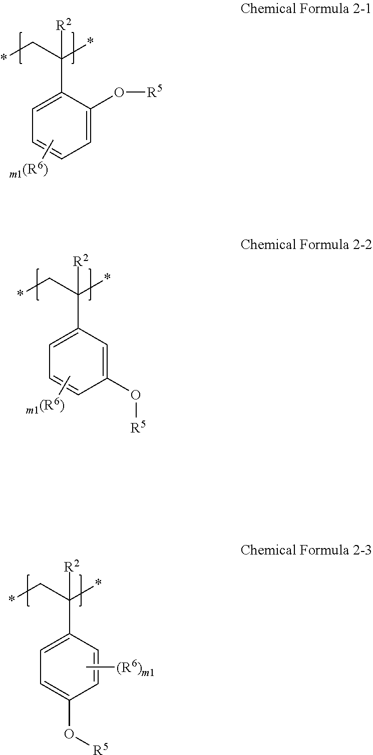

In Chemical Formulas 2-1 to 2-3,
R² may be hydrogen or a methyl group,
R⁵ may be hydrogen or C(═O)R⁷,
R⁷ may be a substituted or unsubstituted C1 to C5 alkyl group,
each R⁶ may independently be hydrogen, a halogen, a hydroxyl group, a substituted or unsubstituted C1 to C5 alkyl group, or a combination thereof,
m1 may be an integer of 1 to 4, and
* may be a linking point.

In Chemical Formulas 2-1 to 2-3, if (e.g., when) m1 is 2 or more, each R⁶ may be different from or identical to each other.

For example, at least one R⁶ may be a halogen.

As an example, at least one R⁶ may be an iodine group.

Sensitivity (e.g., of the photoresist film) can be further improved if (e.g., when) the second structural unit includes the iodine group.

For example, the second structural unit may be selected from Group II.

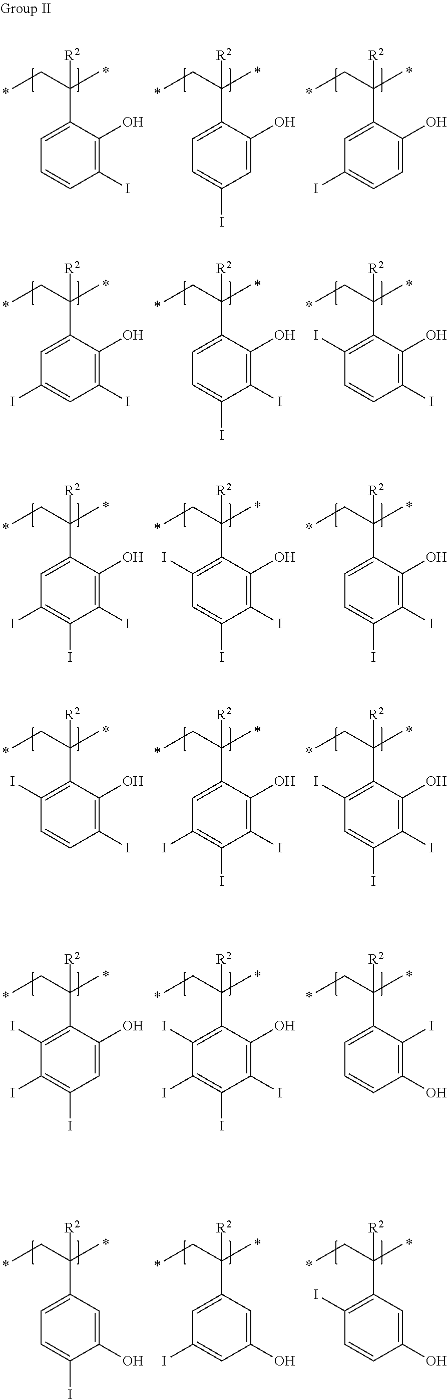

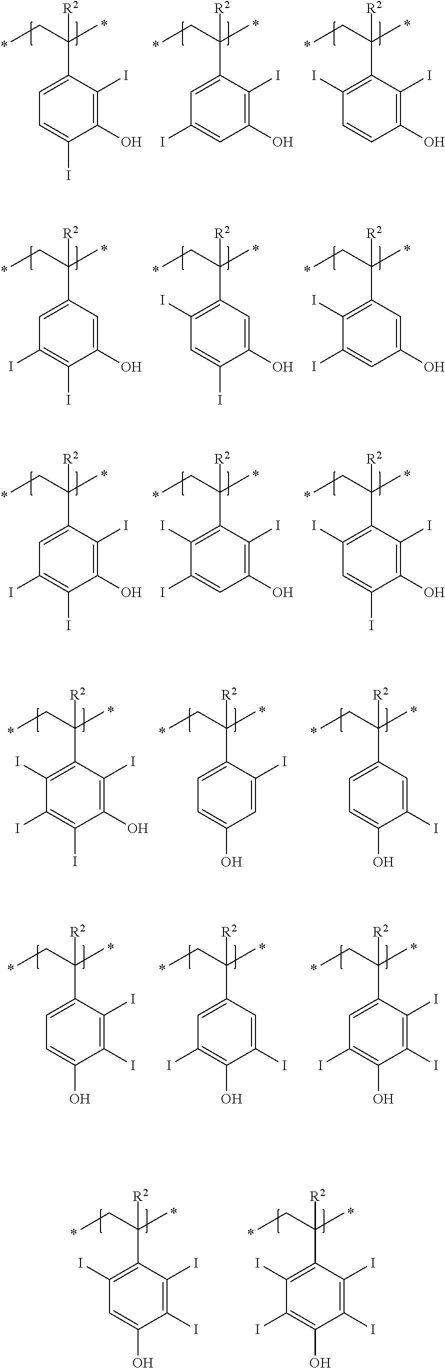

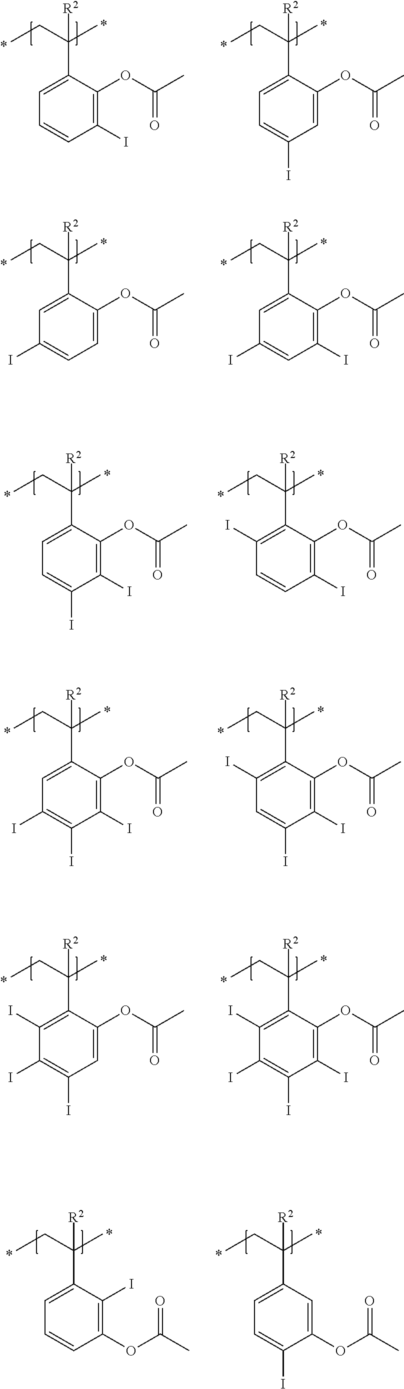

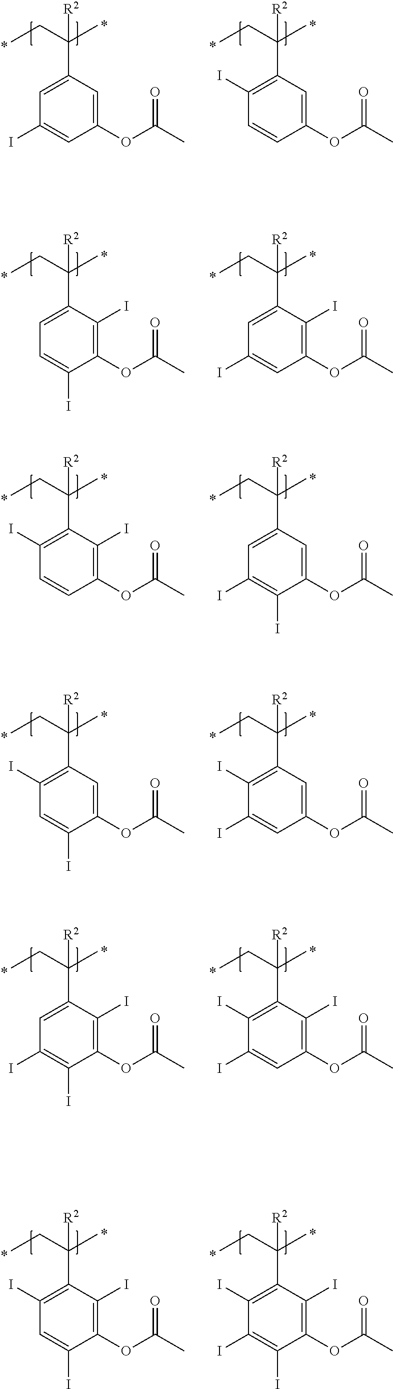

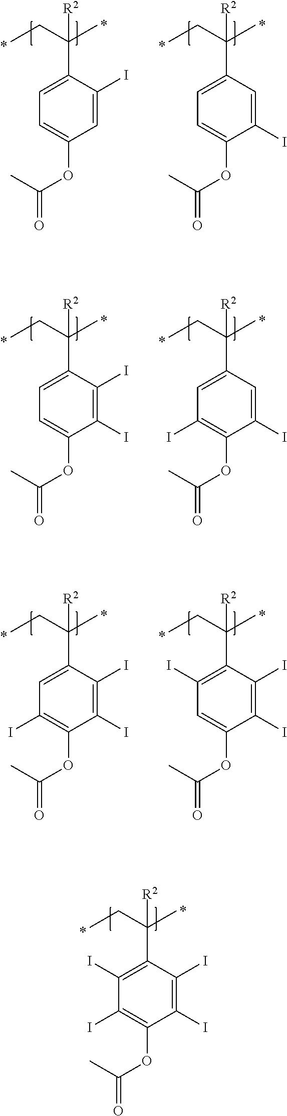

In Group II,
R² may be hydrogen or a methyl group, and * may be a linking point.
R⁸ may be a substituent other than hydrogen and A may be linked to the copolymer main chain (i.e., the polymer backbone of the copolymer) by a quaternary carbon.

For example, R⁸ may be a substituted or unsubstituted C1 to C10 alkyl group and as an example, R⁸ may be a substituted or unsubstituted C1 to C6 alkyl group, such as a methyl group, an ethyl group, a propyl group, a butyl group, an iso-propyl group, an iso-butyl group, a sec-butyl group, and/or the like.

For example, A may be a substituted or unsubstituted cyclobutyl group, a substituted or unsubstituted cyclopentyl group, a substituted or unsubstituted cyclohexyl group, a substituted or unsubstituted cyclooctyl group, a substituted or unsubstituted bicyclohexyl group, a substituted or unsubstituted bicycloheptyl group, a substituted or unsubstituted bicyclooctyl group, a substituted or unsubstituted bicyclononyl group, a substituted or unsubstituted bicyclodecanyl group, a substituted or unsubstituted tricyclodecanyl group, or a substituted or unsubstituted tetracyclodecanyl, and A may be a group which may be linked to the copolymer main chain (i.e., the polymer backbone of the copolymer) by a quaternary carbon.
A may be selected from Group III.

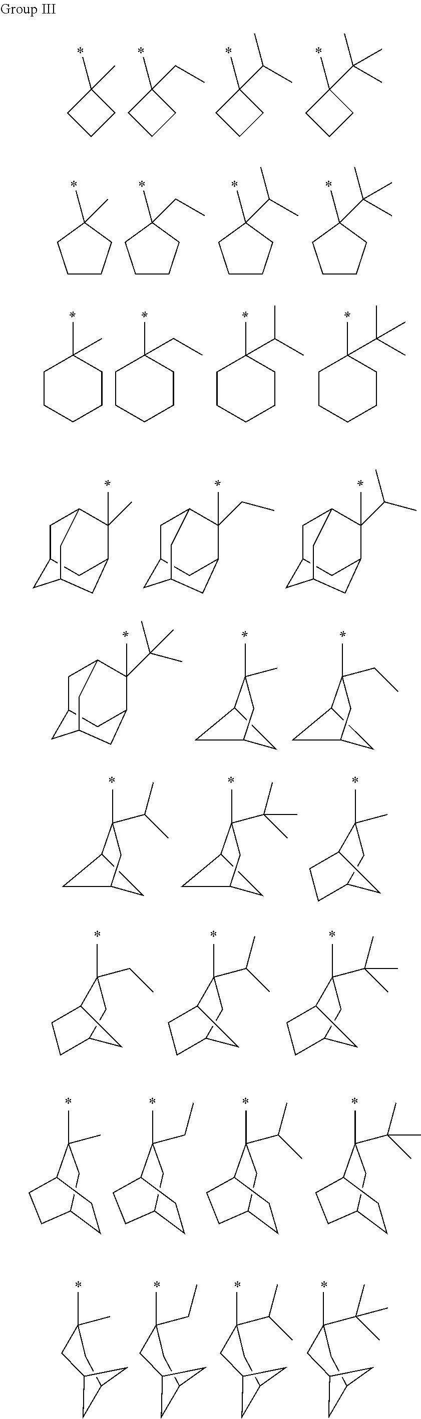

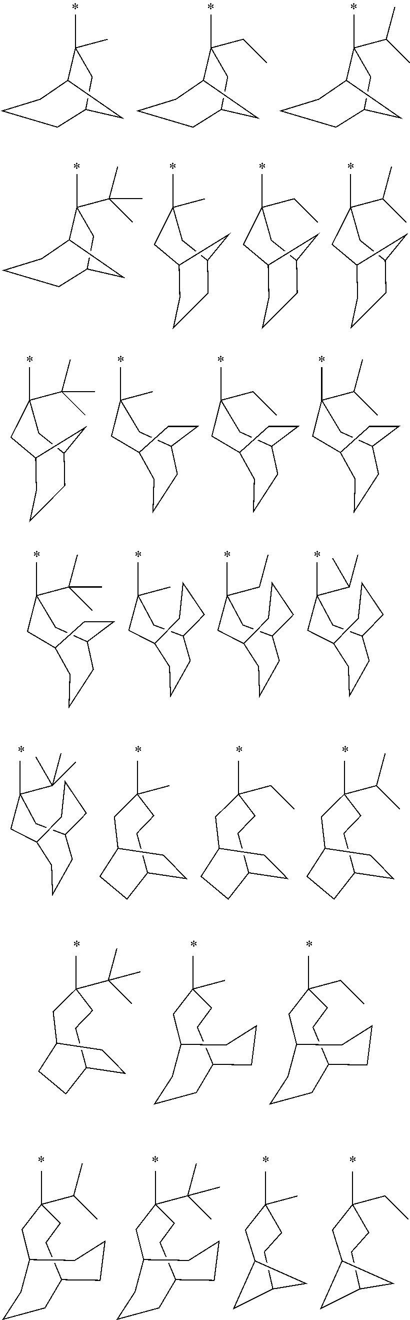

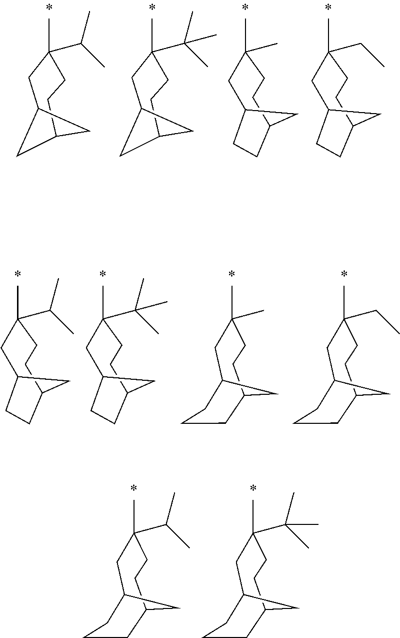

In Group III, * may be a linking point.

The quencher (PDQ) according to some example embodiments may be, for example, an ionic compound. In some embodiments, a sulfonium cation may be included and a sulfonimide anion or a carboxylate anion may be included. The PDQ can improve the IPU or LWR by selectively quenching the acid generated on the photoresist (e.g., film) in the exposed region to improve a pattern profile.

As described herein, PDQ according to one or more embodiments may include a cation represented by Chemical Formula 3A or 3B and an anion represented by Chemical Formula 4A or 4B.

For example, R⁹ to R¹⁴ may each independently be hydrogen, a fluoro group, an iodo group, or a substituted or unsubstituted C1 to C10 alkyl group.

As an example, R⁹ to R¹⁴ may each independently be hydrogen, a fluoro group, an iodo group, a methyl group, an ethyl group, a propyl group, a butyl group, an iso-propyl group, an iso-butyl group, or a sec-butyl group.

The photodecomposable quencher (PDQ) may be represented by Chemical Formula Q1, Q2, or Q3.

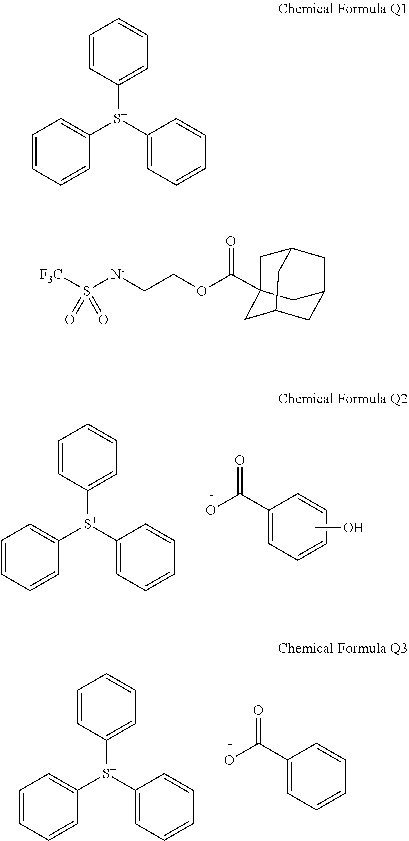

For example, the copolymer may include about 70 to about 99 mol % of the first structural unit and about 1 to about 30 mol % of the second structural unit.

For example, the copolymer may include about 75 to about 99 mol % of the first structural unit and about 1 to about 25 mol % of the second structural unit, and more specifically, the copolymer may include about 80 to about 95 mol % of the first structural unit and about 5 to about 20 mol % of the second structural unit.

For example, the copolymer may include about 30 to about 95 mol % of the first structural unit, about 1 to about 20 mol % of the second structural unit, and about 5 to about 50 mol % of the third structural unit.

For example, the copolymer may include about 55 to about 90 mol % of the first structural unit, about 5 to about 15 mol % of the second structural unit, and about 5 to about 30 mol % of the third structural unit, and more specifically the copolymer may include about 60 to about 85 mol % of the first structural unit, about 5 to about 15 mol % of the second structural unit, and about 5 to about 25 mol % of the third structural unit.

If (e.g., when) the mole ratio of each structural unit included in the copolymer is within the described range, solubility in an organic solvent is improved, and thus it may be uniformly coated on the pattern(s).

The copolymer may have a weight average molecular weight (Mw) of about 1,000 g/mol to about 50,000 g/mol. For example, it may have a weight average molecular weight of about 2,000 g/mol to about 30,000 g/mol, for example, about 3,000 g/mol to about 20,000 g/mol, or for example, about 4,000 g/mol to about 10,000 g/mol, but is not limited thereto. If (e.g., when) the weight average molecular weight of the copolymer is within the described range, a carbon content (e.g., amount) and solubility in a solvent of the resist topcoat composition including the copolymer may be improved or optimized.

The copolymer may be included in an amount of about 0.1 wt % to about 10 wt % based on a total weight of the resist topcoat composition. Within the described range, the resist topcoat may be easily removed.

The photodecomposable quencher (PDQ) may be included in about 0.1 part by weight to about 20 parts by weight, for example, about 0.5 parts by weight to about 15 parts by weight, for example, about 0.5 parts by weight to about 10 parts by weight based on 100 parts by weight of the copolymer. Within the described range, solubility may be improved or optimized and a pattern LWR improvement effect may be achieved (e.g., secured).

For example, the solvent may be an ether-based solvent.

For example, the solvent may be a mixed solvent of an ether-based solvent and an alcohol-based solvent.

The mixed solvent may include the ether-based solvent and the alcohol-based solvent in a mass ratio of about 99.9:0.1 to about 80:20, for example, about 99.5:0.5 to about 85:15, for example, about 99:1 to about 90:10. If (e.g., when) the mixing ratio of the solvents is as described, the solubility of PDQ may be further increased.

The ether-based solvent may be represented by Chemical Formula 5.

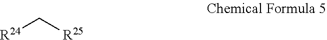

In Chemical Formula 5,
R²⁴ and R²⁵ may each independently be a substituted or unsubstituted C3 to C20 alkyl group.

For example, the ether-based solvent may be selected from among diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, 2-octanone, 4-heptanone, and a combination thereof.

For example, the alcohol-based solvent may be propylene glycol monomethyl ether (PGME), propylene glycol monoethyl ether (PGEE), 4-methyl-2-pentanol, ethyl lactate, methyl 2-hydroxyiso butyrate and/or the like.

The solvent may have sufficient solubility or dispersibility for the resist topcoat composition disclosed herein.

In some embodiments, the resist topcoat composition may further include at least one other polymer selected from among an epoxy-based resin, a novolac resin, a glycoluril-based resin, and a melamine-based resin, but is not limited thereto.

The resist topcoat composition may further include an additive including a surfactant, a thermal acid generator, a plasticizer, or a combination thereof.

The surfactant may be, for example, an alkylbenzene sulfonic acid salt, an alkylpyridinium salt, polyethylene glycol, a quaternary ammonium salt, and/or the like, but is not limited thereto.

The thermal acid generator may be, for example, an acid compound such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, naphthalene carboxylic acid and/or benzointosylate, 2-nitrobenzyl tosylate, and other organic sulfonic acid alkyl esters, but is not limited thereto.

The amount of these additives utilized can be easily adjusted according to desired or suitable physical properties and may not be provided.

In some embodiments, according to some example embodiments, a method of forming patterns utilizing the resist (e.g., photoresist) topcoat composition disclosed herein may be provided. For example, the manufactured patterns may be resist patterns (e.g., photoresist patterns).

A method of forming patterns according to some example embodiments includes coating and heating a photoresist composition on a substrate to form a photoresist film (e.g., coating the photoresist composition on the substrate then heating to form the photoresist film), coating and heating the resist (e.g., photoresist) topcoat composition disclosed herein on the photoresist film to form a photoresist topcoat (e.g., coating the resist topcoat composition disclosed herein on the photoresist film, then heating to form the photoresist topcoat), and exposing and developing the photoresist topcoat and the photoresist film to form the patterns (e.g., resist patterns (e.g., photoresist patterns)).

Hereinafter, a method of forming patterns utilizing the resist (e.g., photoresist) topcoat composition disclosed herein will be described with reference to the drawing. The drawing is a schematic view for explaining a method of forming patterns utilizing a resist (e.g., photoresist) topcoat composition according to the present disclosure.

Referring to the drawing, first, an object to be etched is prepared. An example of the object to be etched may be a thin film formed on a semiconductor substrate. Hereinafter, only the case where the object to be etched is a thin film 100 will be described. The surface of the thin film 100 is cleaned to remove contaminants remaining on the thin film 100. The thin film 100 may be, for example, a silicon nitride film, a polysilicon film, or a silicon oxide film.

A photoresist composition is coated on the thin film 100 and heated to form a photoresist film 101 (e.g., shown in Stage 1). Subsequently, the resist (e.g., photoresist) topcoat composition is coated on the photoresist film 101 and heated to form a photoresist topcoat 30 (e.g., shown in Stage 2).

The heating may be performed at a temperature of about 80° C. to about 500° C.

Then, the photoresist topcoat 30 and the photoresist film 101 are covered by a patterned mask and exposed to high-energy radiation.

For example, the high-energy radiation that can be utilized in the exposure process may include light having a high-energy wavelength, such as EUV (Extreme Ultraviolet; wavelength: 13.5 nm) and E-Beam (electron beam).

A post-exposure heat treatment (PEB) is then performed. The post-exposure heat treatment may be performed at a temperature of about 80° C. to about 200° C. By performing the post-exposure heat treatment, an exposed region of the photoresist film 101, that is, chemical properties of a region not covered by the patterned mask may be changed to a chemical property that is soluble in a developer, so that the exposed region has a different solubility from that of an unexposed region of the photoresist film 101.

A photoresist pattern 102b may be formed by dissolving and removing the photoresist film 101 corresponding to the exposed region and the photoresist topcoat 30 utilizing a developer (e.g., shown in Stage 3).

For example, the developer may be an alkaline developer or a developer containing an organic solvent (hereinafter referred to as an organic-based developer).

As the alkaline developer, a quaternary ammonium salt such as tetramethylammonium hydroxide may be utilized, but aqueous alkaline solutions such as inorganic alkalis, primary to tertiary amines, alcohol amines, and/or cyclic amines may also be utilized.

In some embodiments, the alkaline developer may include (e.g., contain) alcohol and/or surfactant in an appropriate or suitable amount. An alkaline concentration of the alkaline developer may be, for example, about 0.1 to about 20 mass %, and a pH of the alkaline developer may be, for example, about 10 to about 15.

The organic-based developer may be a developer containing at least one organic solvent selected from the group consisting of ketone solvents, ester solvents, alcohol solvents, amide solvents, ether solvents, and hydrocarbon solvents.

Examples of the ketone solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and/or the like.

Examples of the ester solvent include methyl acetate, butyl acetate, ethyl acetate, isopropyl acetate, pentyl acetate, isopentyl acetate, amyl acetate, propylene glycol monomethyl ether acetate, and ethylene glycol monoethyl ether acetate; ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and/or the like.

Suitable solvents may be utilized as alcohol solvents, amide solvents, ether solvents, and hydrocarbon solvents.

A plurality of said solvents may be mixed, or may be mixed with solvents or water other than the described solvents. A moisture content (e.g., amount) as a whole of the developer may be desirably less than about 50 wt %, less than about 20 wt %, or less than about 10 wt %, and the developer may be substantially free of moisture.

A content (e.g., amount) of the organic solvent may be about 50 to about 100 wt %, about 80 to about 100 wt %, about 90 to about 100 wt %, or about 95 to about 100 wt % based on a total amount of the organic developer. 1 [00222] The organic developer may include an appropriate or suitable amount of a suitable surfactant as required.

A content (e.g., amount) of the surfactant may be about 0.001 to about 5 wt %, about 0.005 to about 2 wt %, or about 0.01 to about 0.5 wt % based on a total amount of the developer.

The organic developer may include the inhibitor as described herein.

Subsequently, the exposed thin film 100 is etched by applying the photoresist pattern 102b as an etching mask. As a result, the thin film 100 is formed into a thin film pattern.

The thin film 100 may be etched, for example, by dry etching utilizing an etching gas, and the etching gas may be, for example, CHF₃, CF₄, Cl₂, BCl₃, and a mixture thereof.

In some embodiments of the exposure process described herein, the thin film pattern formed utilizing the photoresist pattern 102b that is formed by the exposure process performed utilizing the EUV light source may have a width corresponding to the photoresist pattern 102b. For example, the photoresist pattern 102b may have a width of about 5 nm to about 100 nm. For example, the thin film pattern formed by the exposure process performed utilizing an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, like the photoresist pattern 102b, and may be formed with (e.g., in) a width of less than or equal to about 20 nm.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

A display device, a display manufacturing device, a pattern forming device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinafter, the present disclosure will be described in more detail through examples relating to the synthesis of the aforementioned polymer and the preparation of a resist topcoat composition including the same. However, the present disclosure is not technically limited by the following examples.

### EXAMPLES

### A. Synthesis of Copolymers

### Synthesis Example 1: Synthesis of Compound 1a

20 g (59.86 mmol) of hexafluoro-2,3-bis(trifluoromethyl)-2,3-butanediol(perfluoropinacol), 7.79 g (59.86 mmol) of 2-(hydroxyethyl)methacrylate, and 18.84 g (71.84 mmol) of triphenylphosphine (PH3P) were mixed in 110 mL of diethylether under a nitrogen atmosphere and then, stirred. After the stirring for 30 minutes, the mixture was cooled down to 0° C., and another mixture of 14.52 g (71.84 mmol) of diisopropylazodicarboxylate (DIAD) and 35 mL of diethylether was slowly added thereto over 2 hours. Subsequently, the obtained mixture was stirred at room temperature 23° C. for 24 hours and then, concentrated. The concentrated mixture was dissolved in dichloromethane and then, treated through column chromatography by utilizing silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate represented by Chemical Formula 1a.
¹H-NMR (Acetone-d6): δ1.90 (3H, t), 4.36 (4H, m), 5.63 (1H, t), 6.09 (1H, t), 8.34 (1H, s)
   ¹⁹F-NMR (Acetone-d6): δ−70.12 (6F, m), −65.38 (6F, m)

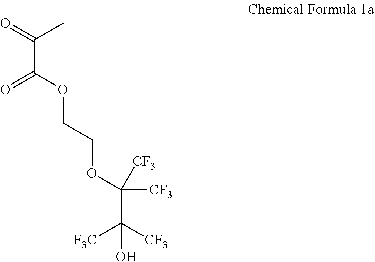 [SMILES: CC(=O)C(=O)OCCOC(C(F)(F)F)(C(F)(F)F)C(O)(C(F)(F)F)C(F)(F)F]

### Synthesis Example 2: Preparation of Copolymer R1

In a 250 mL 2-neck round bottom flask, a compound represented by Chemical Formula 1a (22.5 g, 50 mmol), a compound represented by Chemical Formula 1b (DIVPA, Songwon Industrial Co., Ltd.) (2.4 g, 6 mmol), a compound represented by Chemical Formula 1c (MCPMA, Songwon Industrial Co., Ltd.) (2.7 g, 16 mmol), and 115 g of diisoamyl ether (DIAE) were put under a nitrogen atmosphere and then, heated to 115° C. If (e.g., when) the internal temperature reached 115° C., 26.5 g of a 25 wt % V-601/DIAE solution (V-601, 6.6 g, 29 mmol) was slowly added thereto, and after 6 hours, the reaction solution was cooled to room temperature and then, concentrated to have a solid content (e.g., amount) of 50%. 270 g of heptane was added to the concentrated solution, and a polymer produced therefrom was filtered. The filtered polymer was completely dissolved in 34 g of DIAE, and 270 g of heptane was added thereto for precipitation, which were twice repeated to obtain precipitates, and the precipitates were completely dried, preparing final Copolymer R1 (Mw=7,000).

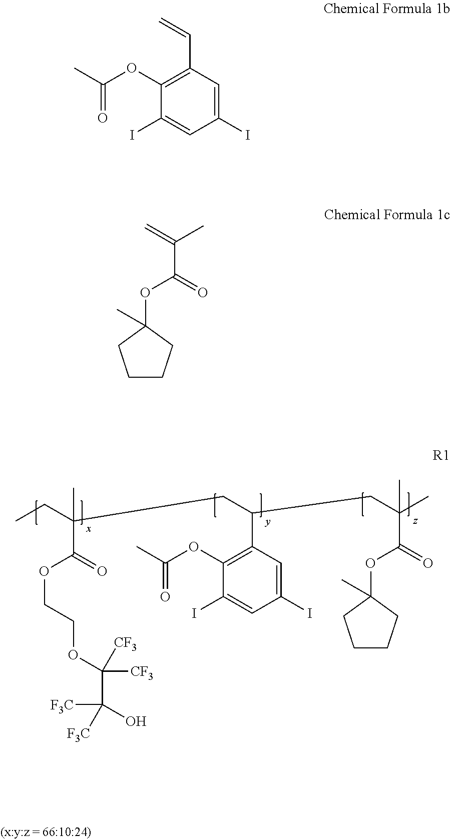

### Synthesis Example 3: Preparation of Copolymer R2

Copolymer R2 (Mw=7,000) was prepared in substantially the same manner as in Synthesis Example 2 except that the compound represented by Chemical Formula 2c (ECPMA, Songwon Industrial Co., Ltd.) (2.9 g, 16 mmol) was utilized instead of the compound represented by Chemical Formula 1c.

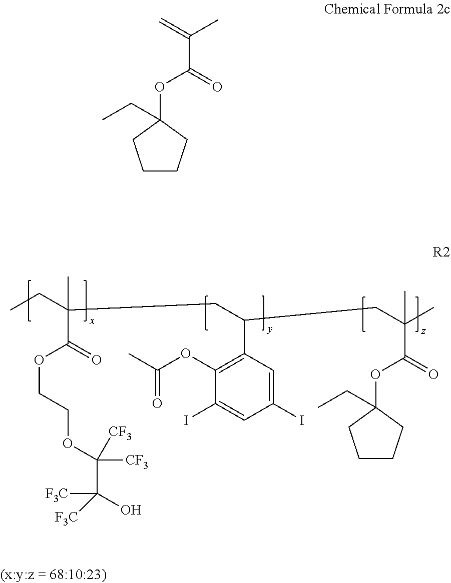

### Synthesis Example 4: Preparation of Copolymer R3

Copolymer R3 (Mw=7,000) was prepared in substantially the same manner as in Synthesis Example 2 except that the compound represented by Chemical Formula 3c (IPCPMA, Songwon Industrial Co., Ltd.) (3.1 g, 16 mmol) was utilized instead of the compound represented by Chemical Formula 1c.

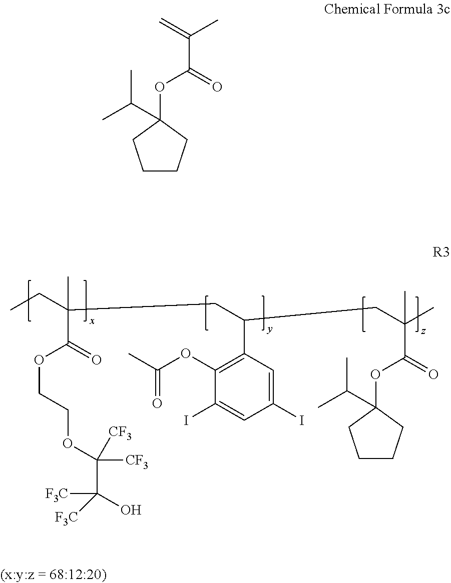

### Synthesis Example 5: Preparation of Copolymer R4

Copolymer R4 (Mw=6,000) was prepared in substantially the same manner as in Synthesis Example 2 except that the compound represented by Chemical Formula 2a (MA-TTPD, Halocarbon, LLC) (14.8 g, 50 mmol) was utilized instead of the compound represented by Chemical Formula 1a.

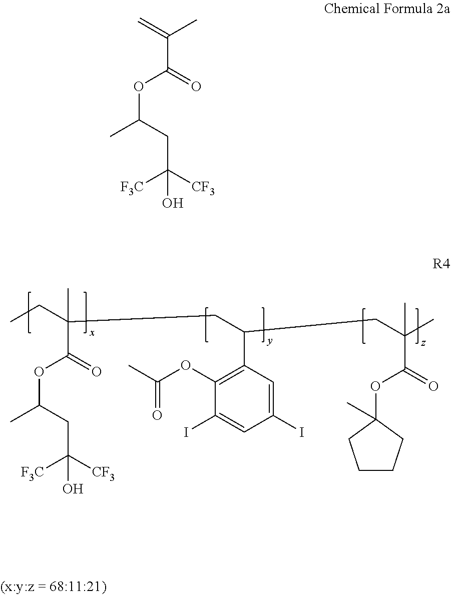

### Synthesis Example 6: Preparation of Copolymer R5

Copolymer R5 (Mw=7,000) was prepared in substantially the same manner as in Synthesis Example 2 except that the compound represented by Chemical Formula 2a (14.8 g, 50 mmol) instead of the compound represented by Chemical Formula 1a and the compound represented by Chemical Formula 2c (2.9 g, 16 mmol) instead of the compound represented by Chemical Formula 1c were utilized.

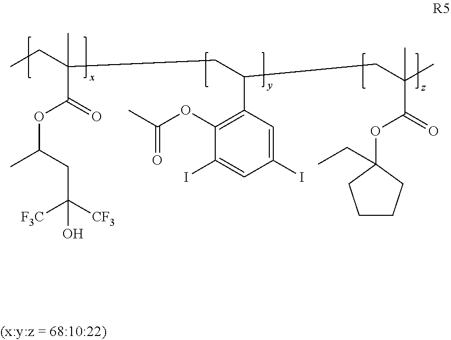

### Synthesis Example 7: Preparation of Copolymer R6

Copolymer R6 (Mw=5,000) was prepared in substantially the same manner as in Synthesis Example 2 except that the compound represented by Chemical Formula 2a (14.8 g, 50 mmol) instead of the compound represented by Chemical Formula 1a and the compound represented by Chemical Formula 3c (3.1 g, 16 mmol) instead of the compound represented by Chemical Formula 1c were utilized.

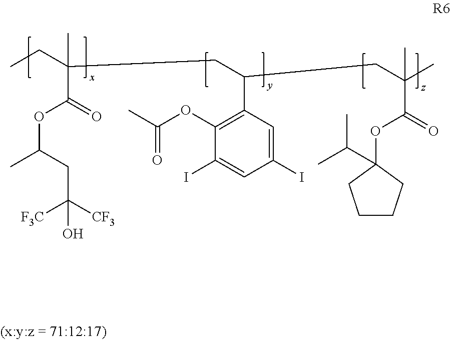

### Synthesis Example 8: Preparation of Copolymer R7

Copolymer R7 (Mw=4,000) was prepared in substantially the same manner as in Synthesis Example 2 except that the compound represented by Chemical Formula 3a (MA-TTPD, Halocarbon, LLC) (14.1 g, 50 mmol) instead of the compound represented by Chemical Formula 1a was utilized.

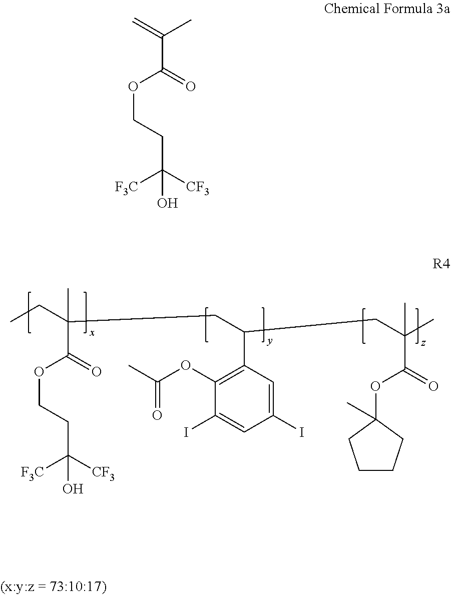

### Synthesis Example 9: Preparation of Copolymer R8

Copolymer R8 (Mw=6,000) was prepared in substantially the same manner as in Synthesis Example 2 except that the compound represented by Chemical Formula 3a (14.1 g, 50 mmol) instead of the compound represented by Chemical Formula 1a and the compound represented by Chemical Formula 2c (2.9 g, 16 mmol) instead of the compound represented by Chemical Formula 1c were utilized.

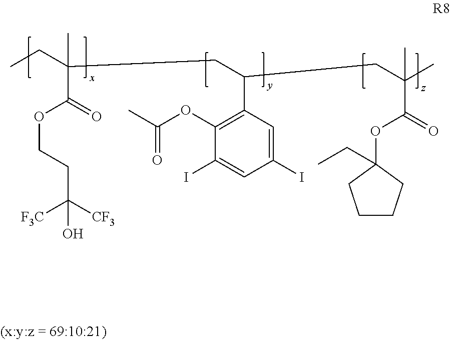

### Synthesis Example 10: Preparation of Copolymer R9

Copolymer R9 (Mw=5,000) was prepared in substantially the same manner as in Synthesis Example 2 except that the compound represented by Chemical Formula 3a (14.1 g, 50 mmol) instead of the compound represented by Chemical Formula 1a and the compound represented by Chemical Formula 2c (3.1 g, 16 mmol) instead of the compound represented by Chemical Formula 1c were utilized.

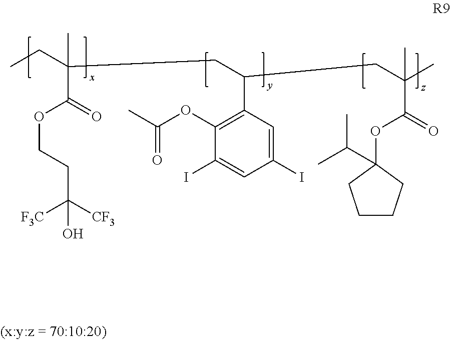

### Synthesis Example 11: Preparation of Copolymer R10

Copolymer R10 (Mw=5,000) was prepared in substantially the same manner as in Synthesis Example 2 except that the compound represented by Chemical Formula 2b (2,4-diiodo-6-vinylphenol, Accela Chembio Inc.) (2.1 g, 6 mmol) instead of the compound represented by Chemical Formula 1b was utilized.

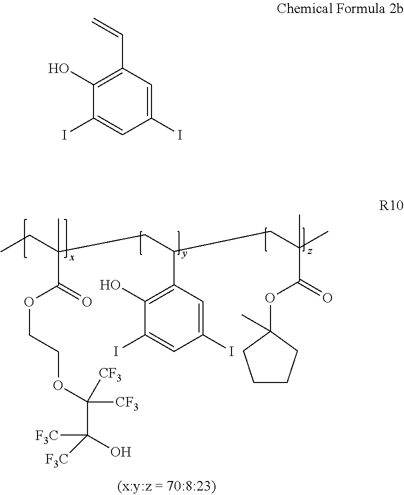

### Synthesis Example 12: Preparation of Copolymer R11

Copolymer R11 (Mw=4,000) was prepared in substantially the same manner as in Synthesis Example 2 except that the compound represented by Chemical Formula 2b (2.1 g, 6 mmol) instead of the compound represented by Chemical Formula 1b and the compound represented by Chemical Formula 2c (2.9 g, 16 mmol) instead of the compound represented by Chemical Formula 1c were utilized.

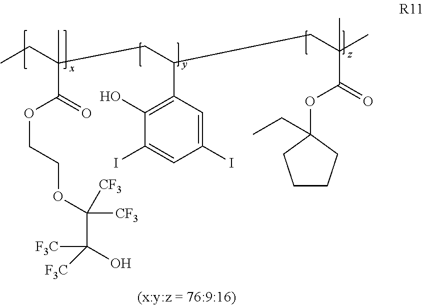

### Synthesis Example 13: Preparation of Copolymer R12

Copolymer R12 (Mw=6,000) was prepared in substantially the same manner as in Synthesis Example 2 except that the compound represented by Chemical Formula 2b (2.1 g, 6 mmol) instead of the compound represented by Chemical Formula 1b and the compound represented by Chemical Formula 3c (3.1 g, 16 mmol) instead of the compound represented by Chemical Formula 1c were utilized.

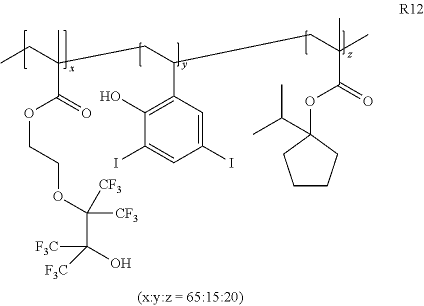

### Synthesis Example 14: Preparation of Copolymer R13

Copolymer R13 (Mw=6,000) was prepared in substantially the same manner as in Synthesis Example 2 except that the compound represented by Chemical Formula 2a (14.8 g, 50 mmol) instead of the compound represented by Chemical Formula 1a and the compound represented by Chemical Formula 2b (2.1 g, 6 mmol) instead of the compound represented by Chemical Formula 1b were utilized.

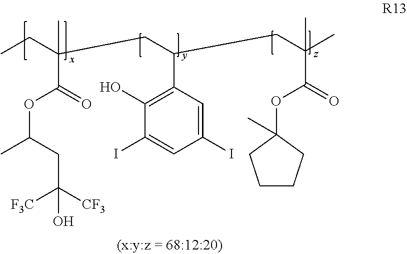

### Synthesis Example 15: Preparation of Copolymer R14

Copolymer R14 (Mw=7,000) was prepared in substantially the same manner as in Synthesis Example 2 except that the compound represented by Chemical Formula 2a (14.8 g, 50 mmol) instead of the compound represented by Chemical Formula 1a, the compound represented by Chemical Formula 2b (2.1 g, 6 mmol) instead of the compound represented by Chemical Formula 1b, and the compound represented by Chemical Formula 2c (2.9 g, 16 mmol) instead of the compound represented by Chemical Formula 1c were utilized.

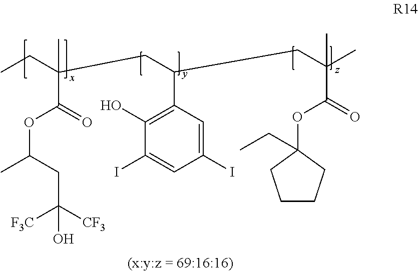

### Synthesis Example 16: Preparation of Copolymer R15

Copolymer R15 (Mw=6,000) was prepared in substantially the same manner as in Synthesis Example 2 except that the compound represented by Chemical Formula 2a (14.8 g, 50 mmol) instead of the compound represented by Chemical Formula 1a, the compound represented by Chemical Formula 2b (2.1 g, 6 mmol) instead of the compound represented by Chemical Formula 1b, and the compound represented by Chemical Formula 3c (3.1 g, 16 mmol) instead of the compound represented by Chemical Formula 1c were utilized.

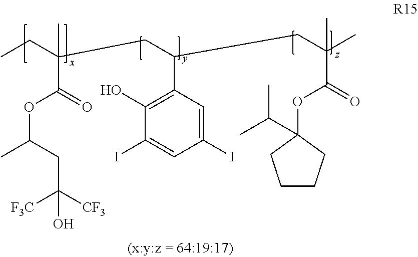

### Synthesis Example 17: Preparation of Copolymer R16

Copolymer R16 (Mw=4,000) was prepared in substantially the same manner as in Synthesis Example 2 except that the compound represented by Chemical Formula 3a (14.1 g, 50 mmol) instead of the compound represented by Chemical Formula 1a and the compound represented by Chemical Formula 2b (2.1 g, 6 mmol) instead of the compound represented by Chemical Formula 1b were utilized

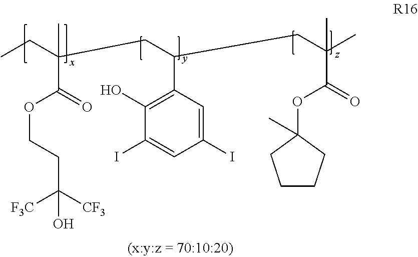

### Synthesis Example 18: Preparation of Copolymer R17

Copolymer R17 (Mw=6,000) was prepared in substantially the same manner as in Synthesis Example 2 except that the compound represented by Chemical Formula 3a (14.8 g, 50 mmol) instead of the compound represented by Chemical Formula 1a, the compound represented by Chemical Formula 2b (2.1 g, 6 mmol) instead of the compound represented by Chemical Formula 1b, and the compound represented by Chemical Formula 2c (2.9 g, 16 mmol) instead of the compound represented by Chemical Formula 1c were utilized.

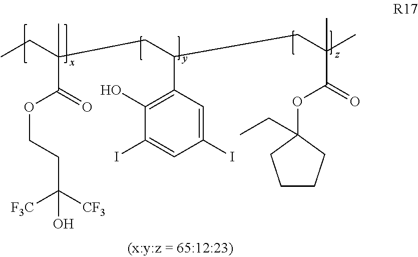

### Synthesis Example 19: Preparation of Copolymer R18

Copolymer R18 (Mw=5,000) was prepared in substantially the same manner as in Synthesis Example 2 except that the compound represented by Chemical Formula 3a (14.8 g, 50 mmol) instead of the compound represented by Chemical Formula 1a, the compound represented by Chemical Formula 2b (2.1 g, 6 mmol) instead of the compound represented by Chemical Formula 1b, and the compound represented by Chemical Formula 3c (3.1 g, 16 mmol) instead of the compound represented by Chemical Formula 1c were utilized.

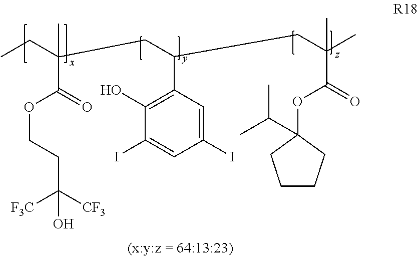

### Comparative Synthesis Example 1: Preparation of Copolymer R19

Copolymer R19 (Mw=5,000) was prepared in substantially the same manner as in Synthesis Example 2 except that butyl methacrylate (BMA,TCI Industrial Chemistry) (7.2 g, 50 mmol) instead of the compound represented by Chemical Formula 1a was utilized.
(x:y:z=68:12:20)

### Comparative Synthesis Example 2: Preparation of Copolymer R20

Copolymer R20 (Mw=6,000) was prepared in substantially the same manner as in Synthesis Example 2 except that butyl methacrylate (7.2 g, 50 mmol) instead of the compound represented by Chemical Formula 1a and the compound represented by Chemical Formula 2c (2.9 g, 16 mmol) instead of the compound represented by Chemical Formula 1c were utilized.

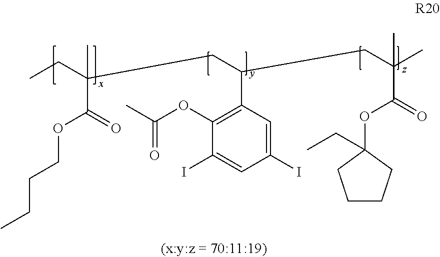

### Comparative Synthesis Example 3: Preparation of Copolymer R21

Copolymer R21 (Mw=7,000) was prepared in substantially the same manner as in Synthesis Example 2 except that butyl methacrylate (7.2 g, 50 mmol) instead of the compound represented by Chemical Formula 1a and the compound represented by Chemical Formula 3c (3.1 g, 16 mmol) instead of the compound represented by Chemical Formula 1c were utilized.

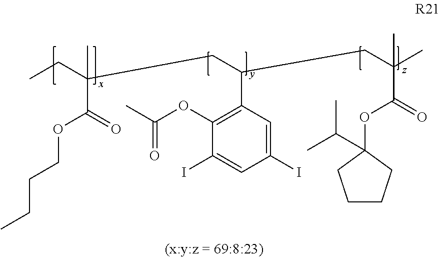

### Comparative Synthesis Example 4: Preparation of Copolymer R22

Copolymer R22 (Mw=7,000) was prepared in substantially the same manner as in Synthesis Example 2 except that butyl methacrylate (7.2 g, 50 mmol) instead of the compound represented by Chemical Formula 1a and the compound represented by Chemical Formula 2b (2.1 g, 6 mmol) instead of the compound represented by Chemical Formula 1b were utilized.

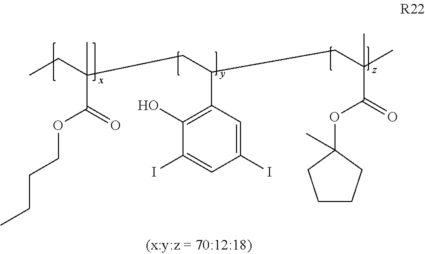

### Comparative Synthesis Example 5: Preparation of Copolymer R23

Copolymer R23 (Mw=5,000) was prepared in substantially the same manner as in Synthesis Example 2 except that butyl methacrylate (7.2 g, 50 mmol) instead of the compound represented by Chemical Formula 1a, the compound represented by Chemical Formula 2b (2.1 g, 6 mmol) instead of the compound represented by Chemical Formula 1b, and the compound represented by Chemical Formula 2c (2.9 g, 16 mmol) instead of the compound represented by Chemical Formula 1c were utilized.

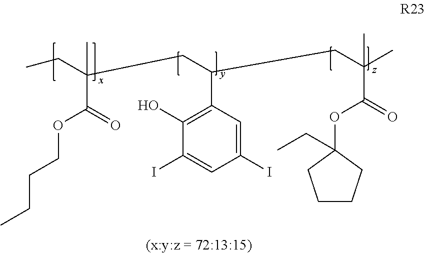

### Comparative Synthesis Example 6: Preparation of Copolymer R24

Copolymer R24 (Mw=6,000) was prepared in substantially the same manner as in Synthesis Example 2 except that butyl methacrylate (7.2 g, 50 mmol) instead of the compound represented by Chemical Formula 1a, the compound represented by Chemical Formula 2b (2.1 g, 6 mmol) instead of the compound represented by Chemical Formula 1b, and the compound represented by Chemical Formula 3c (3.1 g, 16 mmol) instead of the compound represented by Chemical Formula 1c were utilized.

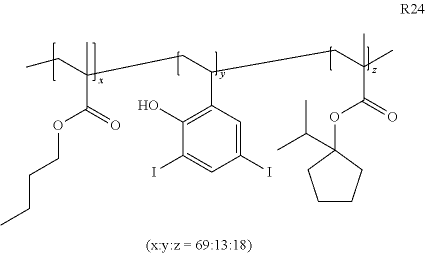

### Comparative Synthesis Example 7: Preparation of Copolymer R25

Copolymer R25 (Mw=5,000) was prepared in substantially the same manner as in Synthesis Example 2 except that the compound represented by Chemical Formula 1a (25.1 g, 56 mmol) and the compound represented by Chemical Formula 1c (2.7 g, 16 mmol) were utilized, but the compound represented by Chemical Formula 1b was not utilized.

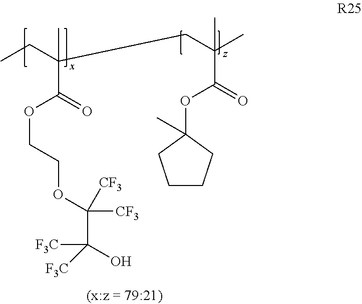

### Synthesis Example 20: Preparation of Copolymer R26

In a 250 mL 2-neck round bottom flask, a compound represented by Chemical Formula 1a (16.1 g, 36 mmol), a compound represented by Chemical Formula 1b (DIVPA, Songwon Industrial Co., Ltd.) (1.7 g, 4 mmol), and 110 g of diisoamyl ether (DIAE) were put under a nitrogen atmosphere and heated to an internal temperature of 85° C. If (e.g., when) the internal temperature reached 85° C., 14.7 g of a 25 wt % V-601/DIAE solution (V-601, 3.7 g, 16 mmol) was slowly added thereto, and after 6 hours, the reaction solution was cooled to room temperature and then, concentrated to have a solid content (e.g., amount) of 50%. To the concentrated solution, 270 g of heptane was added, and a polymer produced therein was filtered. 34 g of the filtered polymer was completely dissolved in DIAE, and 270 g of heptane was added thereto for precipitation, which were twice repeated, and precipitates therefrom were completely dried, finally obtaining Copolymer R26 (Mw=4,000).

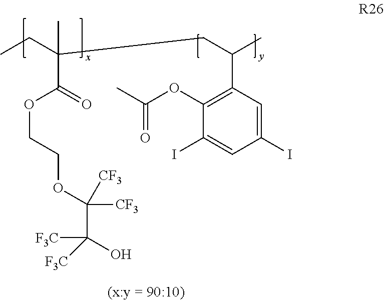

### Synthesis Example 21: Preparation of Copolymer R27

Copolymer R27 (Mw=9,000) was prepared in substantially the same manner as in Synthesis Example 20 except that the compound represented by Chemical Formula 2b (2,4-diiodo-6-vinylphenol, Accela Chembio Inc.) (1.5 g, 16 mmol) instead of the compound represented by Chemical Formula 1b was utilized.

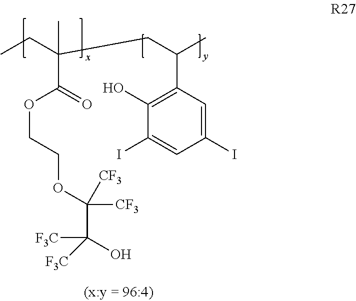

### Synthesis Example 22: Preparation of Copolymer R28

Copolymer R28 (Mw=5,000) was prepared in substantially the same manner as in Synthesis Example 20 except that the compound represented by Chemical Formula 2a (10.6 g, 36 mmol) instead of the compound represented by Chemical Formula 1a was utilized.

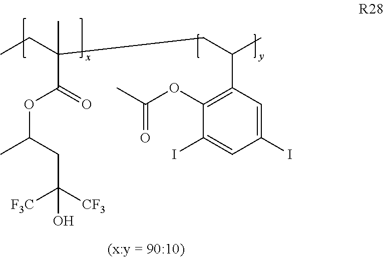

### Synthesis Example 23: Preparation of Copolymer R29

Copolymer R29 (Mw=6,000) was prepared in substantially the same manner as in Synthesis Example 20 except that the compound represented by Chemical Formula 2a (16.1 g, 36 mmol) instead of the compound represented by Chemical Formula 1a and the compound represented by Chemical Formula 2b (1.5 g, 4 mmol) instead of the compound represented by Chemical Formula 1b were utilized.

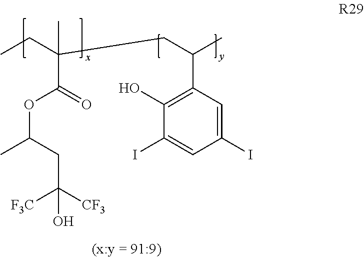

### Synthesis Example 24: Preparation of Copolymer R30

Copolymer R30 (Mw=5,000) was prepared in substantially the same manner as in Synthesis Example 20 except that the compound represented by Chemical Formula 3a (MA-TTBD, Halocarbon LLC.) (10.1 g, 36 mmol) instead of the compound represented by Chemical Formula 1a was utilized.

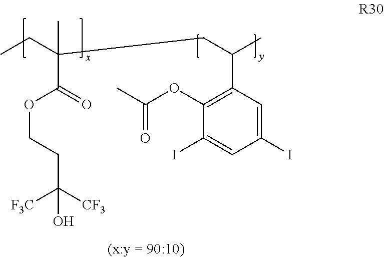

### Synthesis Example 25: Preparation of Copolymer R31

Copolymer R31 (Mw=5,000) was prepared in substantially the same manner as in Synthesis Example 20 except that the compound represented by Chemical Formula 3a (10.1 g, 36 mmol) instead of the compound represented by Chemical Formula 1a and the compound represented by Chemical Formula 2b (1.5 g, 4 mmol) instead of the compound represented by Chemical Formula 1b were utilized.

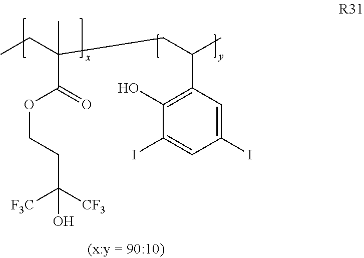

### B. Preparation of Resist Topcoat Compositions

### Example 1

0.5 wt % of Copolymer R1 according to Synthesis Example 2 was dissolved in 100 g of DIAE and then, stirred at room temperature (23° C.) for 24 hours and filtered through a TEFLON (tetrafluoroethylene) filter with a pore size of 0.45 micrometer (μm), preparing a resist topcoat composition according to Example 1.

### Examples 2 to 18 and Comparative Examples 1 and 7

Each resist topcoat composition was prepared in substantially the same manner as in Example 1 except that the copolymers according to Synthesis Examples 3 to 19 and Comparative Synthesis Examples 1 to 7 were respectively utilized instead of Copolymer R1.

### Example 19

0.98 g (0.5 wt %) of Copolymer R1 according to Synthesis Example 2 and 0.013 g (0.007 wt %) of a photodecomposable quencher (PDQ) Q1 were dissolved in 199 g of a mixed solvent of DIAE/PGME (w/w=97/3) and then, stirred at room temperature (23° C.) for 24 hours and filtered through a TEFLON (tetrafluoroethylene) filter with a pore size of 0.45 μm, preparing a resist topcoat composition.

### Examples 20 to 28

Each resist topcoat composition was prepared in substantially the same manner as in Example 19 except that the copolymer and a type or kind of the photodecomposable quencher (PDQ) were respectively changed as shown in Table 2.

### Comparative Example 8

A resist topcoat composition was prepared in substantially the same manner as in Example 19 except that the photodecomposable quencher (PDQ) was not utilized.

### C. Evaluation Examples

### Evaluation 1: Solubility Evaluation

Each of the copolymers of Synthesis Examples 2 to 25 and Comparative Synthesis Examples 1 to 7 was taken by 1 g and added to 50 g of DIAE (2 wt %) and then, stirred for 24 hours and examined with respect to whether or not precipitates were produced with inspection by naked eyes, and the results are shown in Tables 1 and 2.

No precipitation is indicated by “solubility” of ◯. Precipitation is indicated by “solubility” of X.

### Evaluation 2: Developability Evaluation

Each of the resist (e.g., photoresist) topcoat compositions according to Synthesis Examples 2 to 25 and Comparative Synthesis Examples 1 to 7 was spin-coated on a silicon substrate and heat-treated at 110° C. on a hot plate for 1 minute, forming an about 5 nanometer (nm)-thick photoresist topcoat (e.g., for a photoresist). The silicon substrate with the photoresist topcoat formed thereon was rinsed with 2.38% tetramethylammonium hydroxide aqueous solution and heat-treated again at 110° C. on the hot plate for 1 minute and then, measured with respect to a thickness change of the photoresist topcoat using Equation 1, and the results are shown in Tables 1 and 2.

Residual film after development (%)=[Topcoat thickness before development (nm)−Topcoat thickness after development (nm)]×100/Topcoat thickness before development (nm) Equation 1

If (e.g., when) “residual film after development” was less than or equal to 20% the developability was “◯”. If (e.g., when) “residual film after development” was greater than 20% the developability was “X”.

### Evaluation 3: Evaluation of Sensitivity and LWR

After forming a resist underlayer (thickness: 50 angstrom (A)) and a photoresist thin film for EUV (a thickness: 700 Å) on a 12-inch silicon substrate, each of the resist (e.g., photoresist) topcoat compositions according to Examples 1 to 28 and Comparative Examples 1 to 8 was spin-coated and then, heat-treated at 110° C. for 1 minute on a hot plate to form an about 5 nm-thick photoresist topcoat (e.g., for a photoresist).

On the wafer on which the photoresist topcoat (e.g., for a photoresist) was formed, line & space patterns were formed in a focus-energy matrix (FEM) format by utilizing NXE3400B EUV equipment. Subsequently, optimum sensitivity capable of forming a critical dimension (CD) of 26.0 nm was checked in an interpolation method, and the results are shown in Tables 1 and 2, and

after checking the optimum or desired sensitivity, a line width roughness (LWR) distribution at the corresponding energy shot was measured by utilizing CD-SEM equipment made by Hitatchi Ltd., and the same patterns at 500 points were measured within the shot in order to assess the reliability of the distribution, and final average values thereof are shown in Tables 1 and 2.

TABLE 1

| | Co- | Solubil- | Develop- | Sensitivity | LWR |
|---|---|---|---|---|---|
| | polymer | ity | ability | (mJ/cm²) | (nm) |
| Example 1 | R1 | ◯ | ◯ | 40.4 | 1.97 |
| Example 2 | R2 | ◯ | ◯ | 40.7 | 1.91 |
| Example 3 | R3 | ◯ | ◯ | 40.8 | 1.84 |
| Example 4 | R4 | ◯ | ◯ | 41.9 | 1.95 |
| Example 5 | R5 | ◯ | ◯ | 41.6 | 1.92 |
| Example 6 | R6 | ◯ | ◯ | 41.5 | 1.86 |
| Example 7 | R7 | ◯ | ◯ | 42.8 | 1.96 |
| Example 8 | R8 | ◯ | ◯ | 42.5 | 1.93 |
| Example 9 | R9 | ◯ | ◯ | 42.7 | 1.88 |
| Example 10 | R10 | ◯ | ◯ | 40.5 | 1.98 |
| Example 11 | R11 | ◯ | ◯ | 40.8 | 1.91 |
| Example 12 | R12 | ◯ | ◯ | 40.6 | 1.86 |
| Example 13 | R13 | ◯ | ◯ | 41.4 | 1.93 |
| Example 14 | R14 | ◯ | ◯ | 41.3 | 1.90 |
| Example 15 | R15 | ◯ | ◯ | 41.7 | 1.88 |
| Example 16 | R16 | ◯ | ◯ | 42.6 | 1.97 |
| Example 17 | R17 | ◯ | ◯ | 42.3 | 1.91 |
| Example 18 | R18 | ◯ | ◯ | 42.6 | 1.85 |
| Comparative | R19 | ◯ | ◯ | 45.1 | 2.07 |
| Example 1 | | | | | |
| Comparative | R20 | ◯ | X | unmea- | unmea- |
| Example 2 | | | | surable | surable |
| Comparative | R21 | ◯ | X | unmea- | unmea- |
| Example 3 | | | | surable | surable |
| Comparative | R22 | ◯ | ◯ | 45.3 | 2.08 |
| Example 4 | | | | | |
| Comparative | R23 | ◯ | ◯ | 45.6 | 2.05 |
| Example 5 | | | | | |
| Comparative | R24 | ◯ | X | unmea- | unmea- |
| Example 6 | | | | surable | surable |
| Comparative | R25 | X | X | unmea- | unmea- |
| Example 7 | | | | surable | surable |

TABLE 2

| | | | | | Sensi- | |
|---|---|---|---|---|---|---|
| | | | Solu- | Develop- | tivity | LWR |
| | Copolymer | PDQ | bility | ability | (mJ/cm²) | (nm) |
| Example 19 | R1 | Q1 | ◯ | ◯ | 40.5 | 1.92 |
| Example 20 | R27 | Q1 | ◯ | ◯ | 40.3 | 1.90 |
| Example 21 | R28 | Q1 | ◯ | ◯ | 41.8 | 1.91 |
| Example 22 | R29 | Q1 | ◯ | ◯ | 41.5 | 1.91 |
| Example 23 | R30 | Q1 | ◯ | ◯ | 42.8 | 1.92 |
| Example 24 | R31 | Q1 | ◯ | ◯ | 42.5 | 1.91 |
| Example 25 | R26 | Q2 | ◯ | ◯ | 40.6 | 1.86 |
| Example 26 | R27 | Q2 | ◯ | ◯ | 40.2 | 1.85 |
| Example 27 | R28 | Q2 | ◯ | ◯ | 41.9 | 1.81 |
| Example 28 | R29 | Q2 | ◯ | ◯ | 41.8 | 1.87 |
| Comparative | R1 | — | ◯ | ◯ | 45.2 | 2.08 |
| Example 8 | | | | | | |

Referring to Tables 1 and 2, if (e.g., when) the resist topcoat composition of each of Examples 1 to 28 according to one or more embodiments of the present disclosure was applied, excellent or suitable solubility, developability, and sensitivity were not only achieved, but as pattern deterioration was suppressed or reduced, an excellent or suitable LWR improvement effect also was obtained.

In contrast, the resist topcoat composition of the Comparative Examples 1 to 8 exhibited no LWR improvement effect.

Hereinbefore, the certain embodiments of the present disclosure have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

### DESCRIPTION OF SYMBOLS

30: photoresist topcoat
100: thin film
101: photoresist film
102b: photoresist pattern

What is claimed is:

1. A resist topcoat composition, comprising
a copolymer comprising a first structural unit represented by Chemical Formula M-1 and a second structural unit represented by Chemical Formula M-2; and
a solvent: 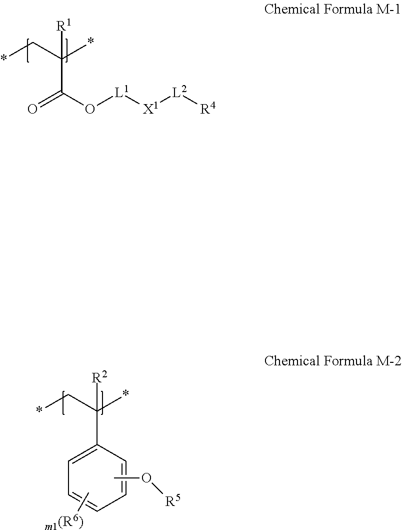
wherein, in Chemical Formulas M-1 and M-2,
R¹ and R² are each independently hydrogen or a substituted or unsubstituted C1 to C10 alkyl group,
L¹ and L² are each independently a single bond, a substituted or unsubstituted C1 to C10 alkylene group, or a combination thereof,
X¹ is a single bond, —O—, —S—, —S(O)—, —S(O)₂—, —C(O)—, —(CO)O—, —O(CO), —O(CO)O—, —NR′-′, or a combination thereof,
R′ is hydrogen, deuterium, or a C1 to C10 alkyl group,
R⁴ is hydrogen, a fluorine, a hydroxyl group, a substituted or unsubstituted C1 to C20 alkyl group, or a combination thereof,
R⁵ is hydrogen or C(═O)R⁷,
R⁷ is a substituted or unsubstituted C1 to C10 alkyl group,
at least one of R⁴, L¹ and L² comprises fluorine and a hydroxyl group,
each R⁶ independently is hydrogen, a halogen, a hydroxyl group, a substituted or unsubstituted C1 to C10 alkyl group, or combination thereof, and
m1 is an integer of 1 to 4.

2. The resist topcoat composition as claimed in claim 1, wherein
the first structural unit represented by Chemical Formula M-1 is represented by Chemical Formula 1: 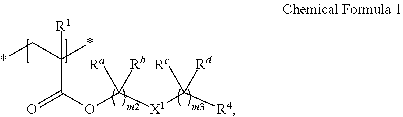
wherein, in Chemical Formula 1,
R¹ is hydrogen or a substituted or unsubstituted C1 to C10 alkyl group,
R^{a}, R^{b}, R^{c}, R^{d}, and R⁴ are each independently hydrogen, fluorine, a hydroxyl group, a substituted or unsubstituted C1 to C20 alkyl group, or a combination thereof,
m2 and m3 are each independently an integer of 1 to 10,
X¹ is a single bond, —O—, —S—, —S(O)—, —S(O)₂—, —C(O)—, —(CO)O—, —O(CO), —O(CO)O—, —NR′—, ′ or a combination thereof,
R′ is hydrogen, deuterium, or a C1 to C10 alkyl group), and
at least one of R^{a}, R^{b}, R^{c}, R^{d}, and R⁴ comprises fluorine and a hydroxyl group.

3. The resist topcoat composition as claimed in claim 2, wherein
at least one of R^{c}, R^{d}, and R⁴ in Chemical Formula 1 comprises fluorine and a hydroxyl group.

4. The resist topcoat composition as claimed in claim 2, wherein
at least one of R^{c} and R^{d} in Chemical Formula 1 is fluorine or a C1 to C10 alkyl group substituted with at least one fluorine, and
R⁴ is a hydroxyl group or a C1 to C10 alkyl group substituted with at least one hydroxyl group.

5. The resist topcoat composition as claimed in claim 2, wherein
at least one of R^{c} and R^{d} in Chemical Formula 1 is a hydroxyl group or a C1 to C10 alkyl group substituted with at least one hydroxyl group, and
R⁴ is fluorine or a C1 to C10 alkyl group substituted with at least one fluorine.

6. The resist topcoat composition as claimed in claim 2, wherein
R^{c} in Chemical Formula 1 is a hydroxyl group or a C1 to C10 alkyl group substituted with at least one hydroxyl group,
R^{d} is fluorine or a C1 to C10 alkyl group substituted with at least one fluorine, and
R⁴ is a hydroxyl group, fluorine, or a C1 to C10 alkyl group substituted with at least one of fluorine or a hydroxyl group.

7. The resist topcoat composition as claimed in claim 1, wherein
the first structural unit is at least one selected from Group I: 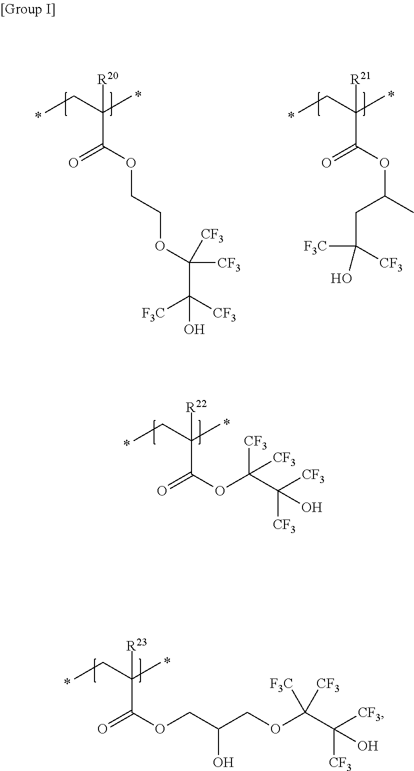
wherein, in Group I,
R²⁰ to R²³ are each independently hydrogen or a methyl group, and
* is a linking point.

8. The resist topcoat composition as claimed in claim 1, wherein
the second structural unit is represented by any one of Chemical Formulas 2-1 to 2-3: 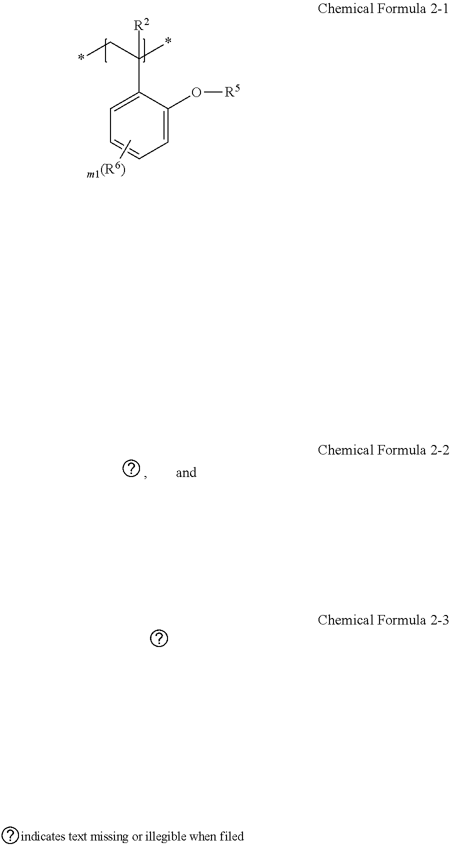
wherein, in Chemical Formulas 2-1 to 2-3,
R² is hydrogen or a methyl group,
R⁵ is hydrogen or C(═O)R⁷,
R⁷ is a substituted or unsubstituted C1 to C5 alkyl group,
each R⁶ independently is hydrogen, a halogen, a hydroxyl group, a substituted or unsubstituted C1 to C5 alkyl group, or a combination thereof,
m1 is an integer of 1 to 4, and
* is a linking point.

9. The resist topcoat composition as claimed in claim 1, wherein
at least one of R⁶ is a halogen.

10. The resist topcoat composition as claimed in claim 1, wherein
at least one of R⁶ is an iodine group.

11. The resist topcoat composition as claimed in claim 1, wherein
the second structural unit is at least one selected from Group II: 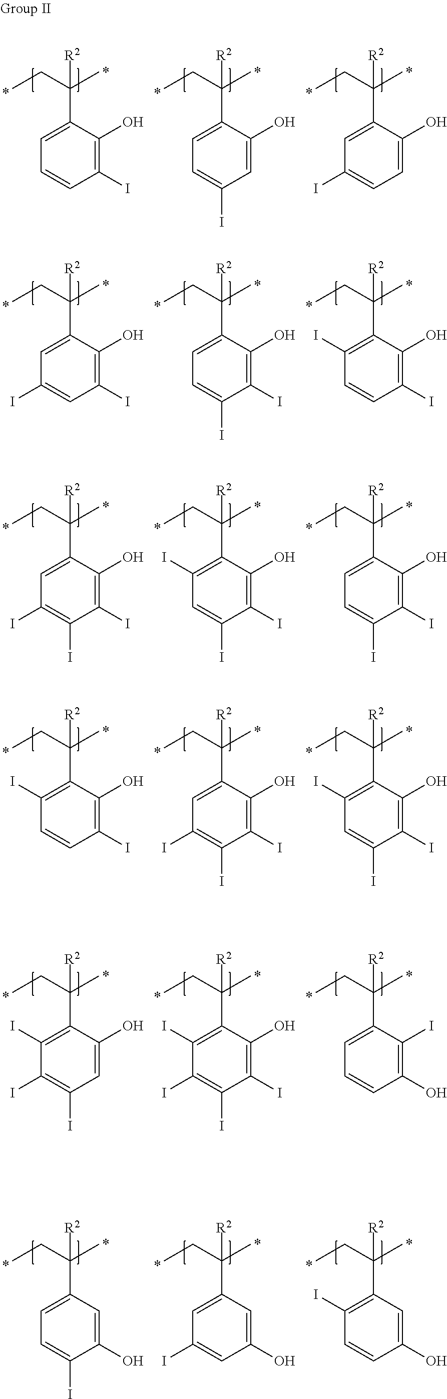 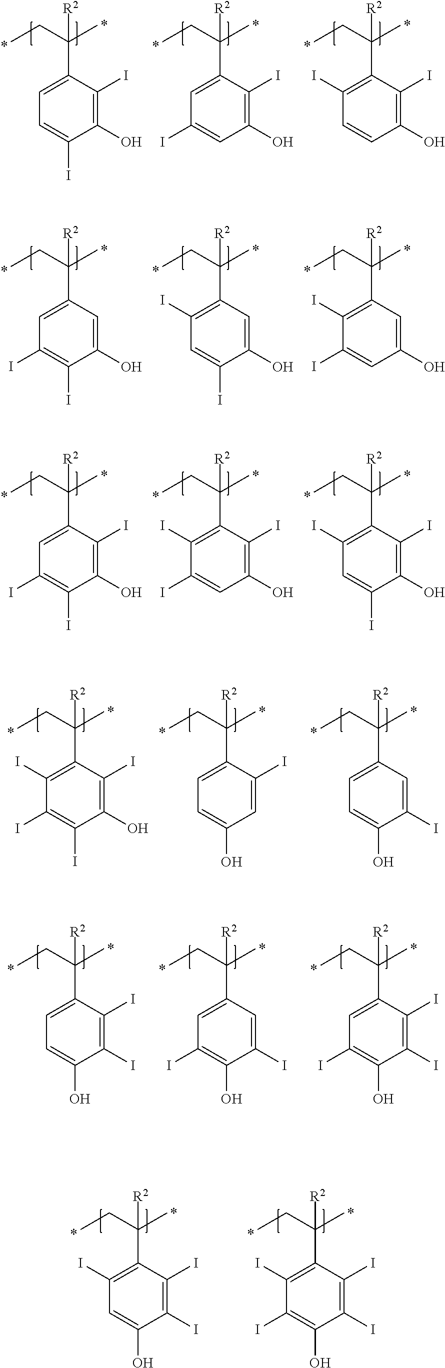 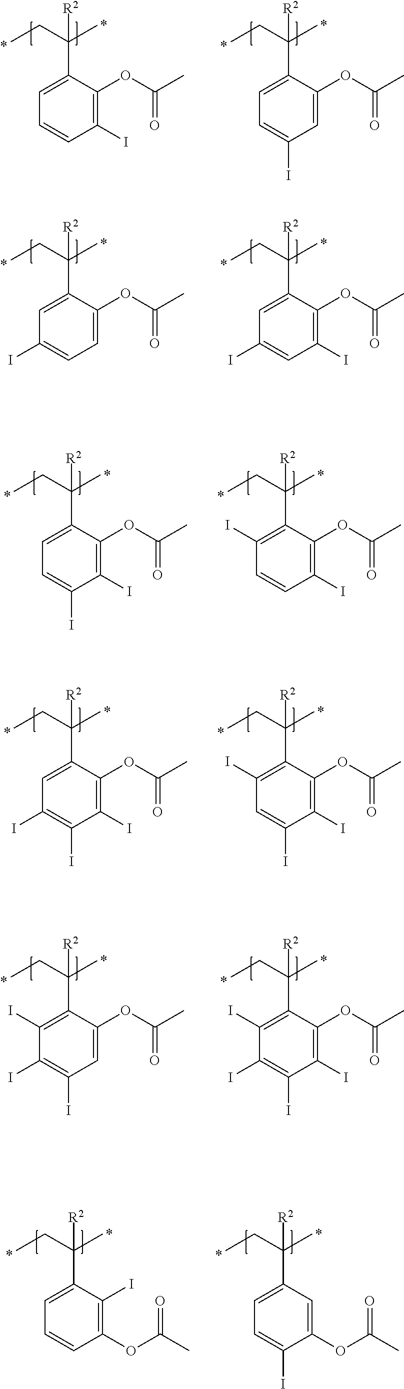 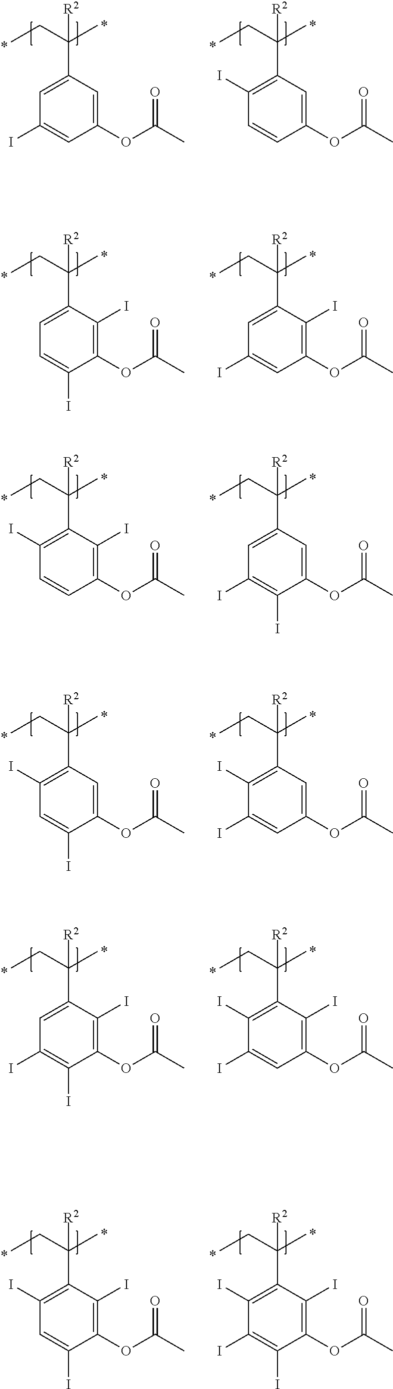 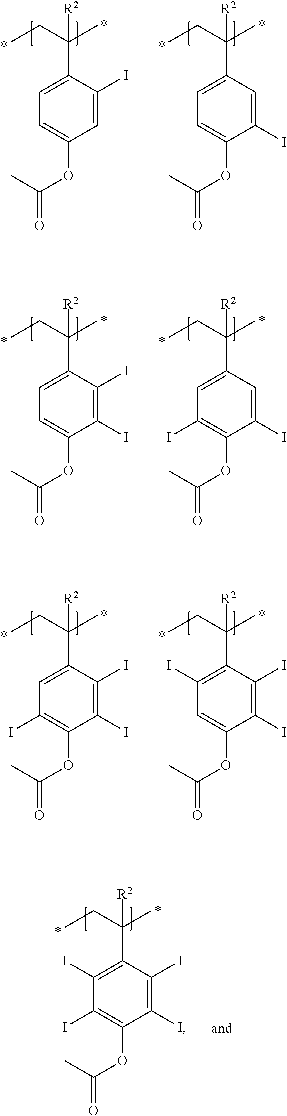
wherein, in Group II,
R² is hydrogen or a methyl group, and
* is a linking point.

12. The resist topcoat composition as claimed in claim 1, wherein
the copolymer further comprises a third structural unit represented by Chemical Formula M-3: 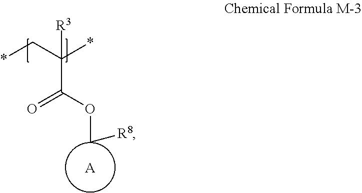
and
wherein, in Chemical Formula M-3,
R³ is hydrogen or a substituted or unsubstituted C1 to C10 alkyl group,
A is a substituted or unsubstituted C4 to C30 monocyclic aliphatic ring group or a substituted or unsubstituted C7 to C50 polycyclic aliphatic ring group, and A is linked to a copolymer main chain by a quaternary carbon,
R⁸ is a substituted or unsubstituted C1 to C10 alkyl group, and
* is a linking point.

13. The resist topcoat composition as claimed in claim 12, wherein
A is a substituted or unsubstituted cyclobutyl group, a substituted or unsubstituted cyclopentyl group, a substituted or unsubstituted cyclohexyl group, a substituted or unsubstituted cyclooctyl group, a substituted or unsubstituted bicyclohexyl group, a substituted or unsubstituted bicycloheptyl group, a substituted or unsubstituted bicyclooctyl group, a substituted or unsubstituted bicyclononyl group, a substituted or unsubstituted bicyclodecanyl group, a substituted or unsubstituted tricyclodecanyl group, or a substituted or unsubstituted tetracyclodecanyl group, and A is linked to the copolymer main chain by a quaternary carbon.

14. The resist topcoat composition as claimed in claim 12, wherein
A is at least one selected from Group III: 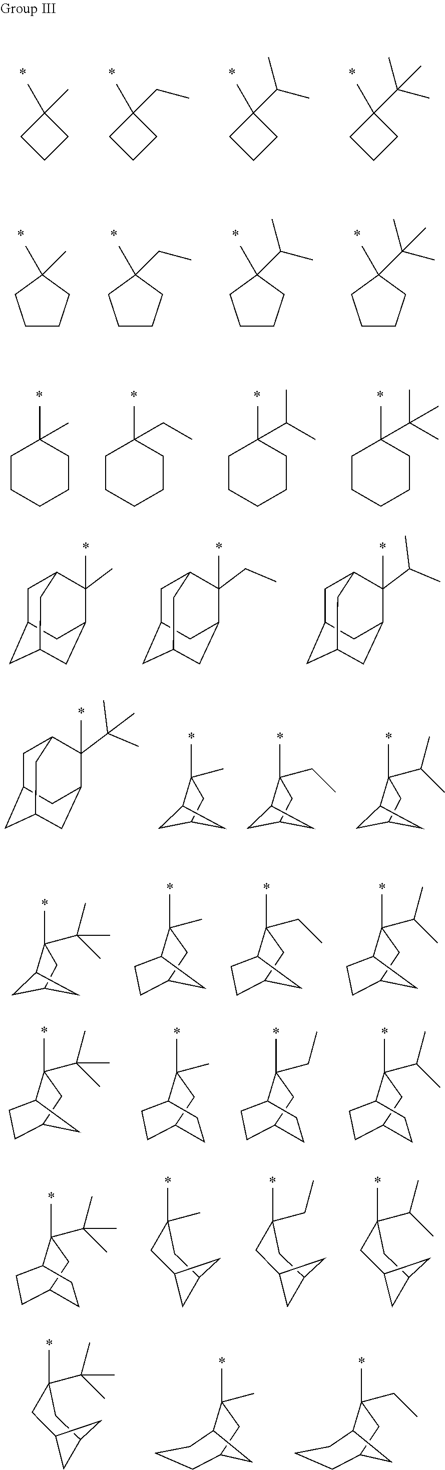 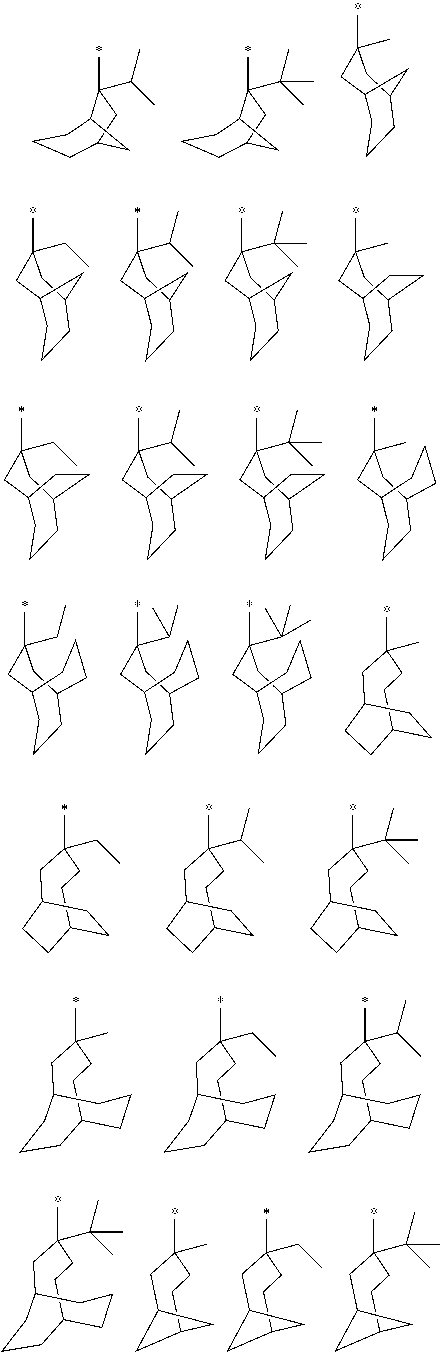 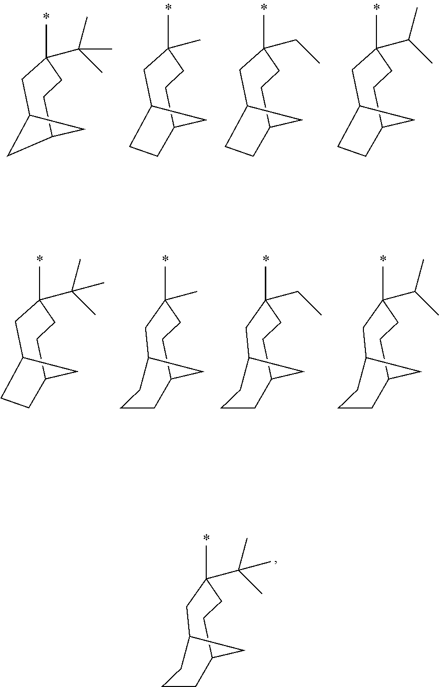
and
wherein, in Group III, * is a linking point.

15. The resist topcoat composition as claimed in claim 12, wherein
the copolymer comprises about 30 to about 95 mole percent (mol %) of the first structural unit, about 1 to about 20 mol % of the second structural unit, and about 5 to about 50 mol % of the third structural unit.

16. The resist topcoat composition as claimed in claim 12, wherein
the copolymer has a weight average molecular weight (Mw) of about 1,000 gram per mole (g/mol) to about 50,000 g/mol.

17. The resist topcoat composition as claimed in claim 12, wherein
the copolymer is in an amount of about 0.1 weight percent (wt %) to about 10 wt % based on a total weight of the resist topcoat composition.

18. The resist topcoat composition as claimed in claim 1, wherein
the resist topcoat composition further comprises a photodecomposable quencher (PDQ) comprising a cation represented by Chemical Formula 3A or 3B and an anion represented by Chemical Formula 4A or 4B: 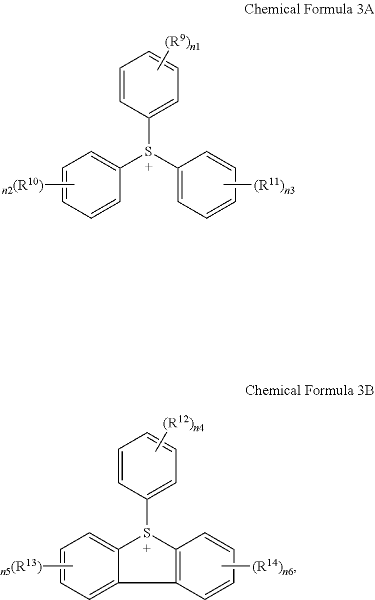
wherein, in Chemical Formulas 3A and 3B,
R⁹ to R¹⁴ are each independently hydrogen, a halogen, a carboxyl group, a substituted or unsubstituted C1 to C10 alkoxy group, or a substituted or unsubstituted C1 to C20 alkyl group, and
n1 to n6 are each independently an integer of 1 to 5, 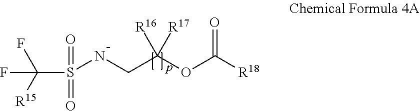 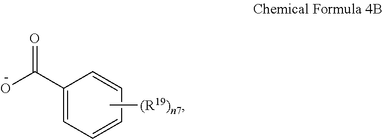
and
wherein, in Chemical Formulas 4A and 4B,
R¹⁵ to R¹⁷ are each independently hydrogen, a halogen, a carboxyl group, a substituted or unsubstituted C1 to C10 alkoxy group, or a substituted or unsubstituted C1 to C20 alkyl group,
R¹⁸ is a substituted or unsubstituted C1 to C20 alkyl group, a substituted or unsubstituted C5 to C30 monocyclic aliphatic ring group, or a substituted or unsubstituted C7 to C50 polycyclic aliphatic ring group,
R¹⁹ is hydrogen, a halogen, a hydroxyl group, a carboxyl group, a substituted or unsubstituted C1 to C10 alkoxy group, or a substituted or unsubstituted C1 to C20 alkyl group,
p is an integer of 1 to 20, and
n7 is an integer of 1 to 5.

19. The resist topcoat composition as claimed in claim 18, wherein
R⁹ to R¹⁴ are each independently hydrogen, a fluoro group, an iodo group, or a substituted or unsubstituted C1 to C10 alkyl group.

20. The resist topcoat composition as claimed in claim 18, wherein
the photodecomposable quencher (PDQ) is represented by Chemical Formula Q1, Q2, or Q3:

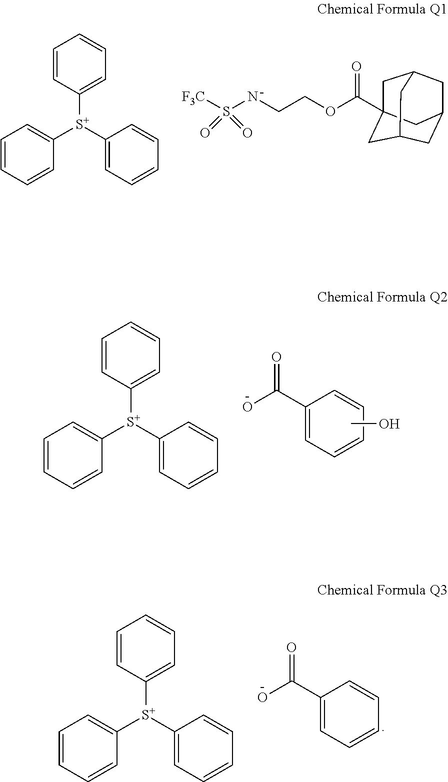

21. The resist topcoat composition as claimed in claim 18, wherein
the photodecomposable quencher (PDQ) is in an amount of about 0.1 part by weight to about 20 parts by weight based on 100 parts by weight of the copolymer.

22. The resist topcoat composition as claimed in claim 1, wherein
the copolymer comprises about 70 to about 99 mol % of the first structural unit and about 1 to about 30 mol % of the second structural unit.

23. The resist topcoat composition as claimed in claim 1, wherein
the copolymer has a weight average molecular weight of about 1,000 g/mol to about 50,000 g/mol.

24. The resist topcoat composition as claimed in claim 1, wherein
the copolymer is in an amount of about 0.1 wt % to about 10 wt % based on a total weight of the resist topcoat composition.

25. The resist topcoat composition as claimed in claim 1, wherein
the solvent is an ether-based solvent represented by Chemical Formula 5: 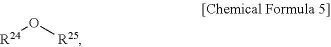
and
wherein, in Chemical Formula 5,
R²⁴ and R²⁵ are each independently a substituted or unsubstituted C3 to C20 alkyl group.

26. The resist topcoat composition as claimed in claim 25, wherein
the solvent is a mixed solvent further comprising an alcohol-based solvent.

27. The resist topcoat composition as claimed in claim 26, wherein
the mixed solvent comprises the ether-based solvent and the alcohol-based solvent in a mass ratio of about 99.9:0.1 to about 80:20.

28. A method of forming patterns, the method comprising
coating and heating a photoresist composition on a substrate to form a photoresist film,
coating and heating the resist topcoat composition as claimed in claim 1 on the photoresist film to form a photoresist topcoat, and
exposing and developing the photoresist topcoat and the photoresist film to form the patterns.
